(19) United States
(12) Patent Application Publication
(10) Pub. No.: US 2024/0194672 A1
(43) Pub. Date: Jun. 13, 2024

(54) MULTI-PITCH PATTERNING THROUGH ONE-STEP FLOW

(71) Applicant: Intel Corporation, Santa Clara, CA (US)

(72) Inventors: Bharath Bangalore Rajeeva, Hillsboro, OR (US); Manish Chandhok, Beaverton, OR (US); Gurpreet Singh, Portland, OR (US); Kevin Huggins, Beaverton, OR (US); Eungnak Han, Portland, OR (US); Florian Gstrein, Portland, OR (US); Marko Radosavljevic, Portland, OR (US)

(73) Assignee: Intel Corporation, Santa Clara, CA (US)

(21) Appl. No.: 18/064,362

(22) Filed: Dec. 12, 2022

(51) Int. Cl. H01L 27/088; H01L 21/02; H01L 21/027; H01L 23/522; H01L 29/10; H01L 29/423

(52) U.S. Cl. CPC H01L 27/088; H01L 21/02164; H01L 21/0217; H01L 21/02271; H01L 21/0271; H01L 23/5226; H01L 29/1033; H01L 29/42364

(57) ABSTRACT

An IC device may include a first conductive structure in a first section and a second conductive structure in a second section. The second conductive structure is in parallel with the first conductive structure in a first direction. A dimension of the second conductive structure in a second direction perpendicular to the first direction is greater than a dimension of the first conductive structure in the second direction. The first conductive structure may be coupled to a channel region of a transistor. The second conductive structure may be coupled to a channel region of another transistor. A first structure comprising a first dielectric material may be over the first conductive structure. A second structure comprising a second dielectric material may be over the second section. A third structure comprising the first dielectric material may be over the second conductive structure and be at least partially surrounded by the second structure.

### BACKGROUND

Integrated circuit (IC) fabrication usually includes two stages. The first stage is referred to as the front end of line (FEOL). The second stage is referred to as the back end of line (BEOL). In the FEOL, individual components (e.g., transistor, capacitors, resistors, etc.) can be patterned in a wafer. In the BEOL, metal layers, vias, and insulating layers can be formed to get the individual components interconnected. The BEOL usually starts with forming the first metal layer on the wafer. The first metal layer is often called M0. More metal layers can be formed on top of M0, and these metal layers are often called M1, M2, and so on.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, and not by way of limitation, in the figures of the accompanying drawings.

FIG. 1 illustrates an IC device comprising an FEOL section and a BEOL section, according to some embodiments of the disclosure.

FIG. 2 illustrates a multi-pitch layer, according to some embodiments of the disclosure.

FIGS. 3A-3D illustrate multi-pitch patterning through directed self-assembly (DSA) of a block copolymer and a cut mask, according to some embodiments of the disclosure.

FIGS. 4A-4D illustrate formation of an oxide layer over a loose pitch region of a multi-pitch layer, according to some embodiments of the disclosure.

FIGS. 5A-5C illustrate formation of nitride structures over a tight pitch region of a multi-pitch layer, according to some embodiments of the disclosure.

FIGS. 6A-6D illustrate formation of extra insulators for a tight pitch region of a multi-pitch layer, according to some embodiments of the disclosure.

FIGS. 7A-7D illustrate multi-pitch patterning based on an oxide structure, according to some embodiments of the disclosure.

FIGS. 8A-8B are top views of a wafer and dies that may include one or more multi-pitch patterns, according to some embodiments of the disclosure.

FIG. 9 is a side, cross-sectional view of an example IC package that may include one or more IC devices having one or more multi-pitch patterns, according to some embodiments of the disclosure.

FIG. 10 is a cross-sectional side view of an IC device assembly that may include components having one or more IC devices implementing one or more multi-pitch patterns, according to some embodiments of the disclosure.

FIG. 11 is a block diagram of an example computing device that may include one or more components with one or more multi-pitch patterns, according to some embodiments of the disclosure.

### DETAILED DESCRIPTION

The systems, methods, and devices of this disclosure each have several innovative aspects, no single one of which is solely responsible for all the desirable attributes disclosed herein. Details of one or more implementations of the subject matter described in this specification are set forth in the description below and the accompanying drawings.

Patterns of metal lines, insulators, or vias in IC devices are often generated through DSA of block copolymers. Phase separation during the DSA of a block copolymer can produce a DSA pattern that includes lamellar structures of polymers. Taking a block copolymer including polymer A and polymer B for example, the DSA of the block copolymer may form lamellar structures including polymer A and lamellar structures including polymer B. The two types of lamellar structures alternate. The center-to-center distance between two adjacent lamellar structures including the same polymer may define a pitch of the DSA pattern.

However, DSA of a block copolymer is limited to a single pitch pattern. The pitch of the DSA pattern is fixed, e.g., based upon the molecular weight of the block copolymer. Examples of pitches of DSA patterns may include, for example, 33 nanometers (nm), 34 nm, 36 nm, 38 nm, 39 nm, and so on. However, the fabrication of an IC device may require formation of a DSA pattern over an underlayer that has a multi-pitch pattern, meaning the underlayer has at least two different pitches. For instance, the layer may have conductive structures (e.g., contacts, metal lines, etc.) that have different dimensions, such as different lengths. The pitch of DSA pattern cannot match all the pitches of the underlayer.

Conventional fabrication technologies usually ensure that the pitch of DSA pattern matches one of the pitches of the underlayer and therefore, is different from other pitches of the underlayer. Given the multi-pitch pattern in the underlayer, the DSA pattern may be inevitably formed over an undesired area, such as the region that has a different pitch from the pitch of the DSA pattern. In a typical flow using these conventional technologies, tight pitches are patterned via DSA, while the loose pitches (such as wide gate, frame, etc.) are cleared off post-DSA using a separate mask. Additionally, another mask is needed to introduce the content back in the cleared off regions. Thus, the conventional technologies can require at least two new masks to clear off the non-compliant pitch regions and add back patterns within these regions. This would add lots of (e.g., over thirty) additional process steps. Thus, the conventional technologies fail to provide an efficient flow for multi-pitch patterning.

Embodiments of the present disclosure may improve on at least some of the challenges and issues described above by using a one-step flow for multi-pitch patterning. For patterning over an underlayer that includes a tight pitch region and a loose pitch region, the one-step flow in the present disclosure can integrate trench patterns of the loose pitch region within plug patterns of the tight pitch region. The integration may be based on the presence of an oxide structure over the loos pitch region, which can eliminate the use of a new mask and therefore, avoid additional process steps.

In various embodiments of the present disclosure, a block copolymer may be provided to a surface of an underlayer having a multi-pitch pattern. The underlayer may include a tight pitch region and a loose pitch region. The tight pitch region may include one or more first conductive structures. The loose pitch region may include one or more second conductive structures. A second conductive structure has a length greater than a first conductive structure. At least one first lamellar structure and at least one second lamellar structure may be formed over the tight pitch region and at least a portion of the loose pitch region through DSA of the block copolymer. The first lamellar structure includes a polymer in the block copolymer, the second lamellar structure includes another polymer in the block copolymer. The second lamellar structure(s) may be removed, e.g., through selective etch. One or more first lamellar structures (if any) that are over the loose pitch region may be removed, e.g., by using a cut mask. A hard mask is then formed. A first portion of the hard mask (e.g., carbon hard mask) may fill openings that are formed by removing one or more second lamellar structures over the tight pitch region. A second portion of the hard mask may be over the one or more first lamellar structures over the tight pitch region and over the first portion of the hard mask.

After the hard mask is formed, an oxide structure over the loose pitch region may be formed. Further, the hard mask can be removed, and one or more openings formed from removing the hard mask may be filled with a dielectric material, such as a nitride, so that a nitride structure can be formed over the first conductive structure. One or more dielectric materials may be provided to form a dielectric structure that at least partially surrounds the nitride structure. A plug may be placed at least partially over the dielectric structure. Another plug may be placed over the oxide structure. A trench over the tight pitch region and a trench over the loose pitch region can be formed based on the plugs. For instance, areas over the tight pitch region and the loose pitch region that are not covered by the plugs may be etched to form the trenches. The trenches may be filled with a dielectric material, such as a nitride, to form a first structure over the tight pitch region and a second structure over the loose pitch region. At least part of the first structure is over the first conductive structure. At least part of the second structure is over the second conductive structure. The second structure over the loose pitch region may be at least partially surrounded by an oxide, e.g., the portion of the oxide structure that is not removed. The oxide may constitute a guard ring of the second conductive structure.

Compared with conventional technologies that requires two hard masks during the fabrication process, the one-step flow requires one hard mask. Thus, the one-step flow has less additional process steps, such as collateral steps needed to add the second hard mask, collateral steps needed to remove the second hard mask, and so on. Thus, the present disclosure provides a more efficient flow for multi-pitch patterning.

It should be noted that, in some settings, the term “nanoribbon” has been used to describe an elongated semiconductor structure that has a substantially rectangular transverse cross-section (e.g., a cross-section in a plane perpendicular to the longitudinal axis of the structure), while the term “nanowire” has been used to describe a similar structure but with a substantially circular or square transverse cross-sections. In the following, a single term “nanoribbon” is used to describe an elongated semiconductor structure independent of the shape of the transverse cross-section. Thus, as used herein, the term “nanoribbon” is used to cover elongated semiconductor structures that have substantially rectangular transverse cross-sections (possibly with rounded corners), elongated semiconductor structures that have substantially square transverse cross-sections (possibly with rounded corners), elongated semiconductor structures that have substantially circular or elliptical/oval transverse cross-sections, as well as elongated semiconductor structures that have any polygonal transverse cross-sections. A longitudinal axis of a structure refers to a line (e.g., an imaginary line) that runs down the center of the structure in a direction perpendicular to a transverse cross-section of the structure.

In the following, some descriptions may refer to a particular source or drain (S/D) region or contact being either a source region/contact or a drain region/contact. However, unless specified otherwise, which region/contact of a transistor or diode is considered to be a source region/contact and which region/contact is considered to be a drain region/contact is not important because, as is common in the field of FETs, designations of source and drain are often interchangeable. Therefore, descriptions of some illustrative embodiments of the source and drain regions/contacts provided herein are applicable to embodiments where the designation of source and drain regions/contacts may be reversed.

As used herein, the term “metal layer” may refer to a layer above a substrate that includes electrically conductive interconnect structures for providing electrical connectivity between different IC components. Metal layers described herein may also be referred to as “interconnect layers” to clearly indicate that these layers include electrically conductive interconnect structures which may, but do not have to be, metal.

The systems, methods and devices of this disclosure each have several innovative aspects, no single one of which is solely responsible for all of the desirable attributes disclosed herein. Details of one or more implementations of the subject matter described in this specification are set forth in the description below and the accompanying drawings.

In the following detailed description, various aspects of the illustrative implementations may be described using terms commonly employed by those skilled in the art to convey the substance of their work to others skilled in the art. For example, the term “connected” means a direct electrical or magnetic connection between the things that are connected, without any intermediary devices, while the term “coupled” means either a direct electrical or magnetic connection between the things that are connected, or an indirect connection through one or more passive or active intermediary devices. The term “circuit” means one or more passive and/or active components that are arranged to cooperate with one another to provide a desired function. If used, the terms “oxide,” “carbide,” “nitride,” etc. refer to compounds containing, respectively, oxygen, carbon, nitrogen, etc., the term “high-k dielectric” refers to a material having a higher dielectric constant (k) than silicon oxide, while the term “low-k dielectric” refers to a material having a lower k than silicon oxide. The terms “substantially,” “close,” “approximately,” “near,” and “about,” generally refer to being within +/−10%, e.g., within +/−5% or within +/−2%, of a target value based on the context of a particular value as described herein or as known in the art. Similarly, terms indicating orientation of various elements, e.g., “coplanar,” “perpendicular,” “orthogonal,” “parallel,” or any other angle between the elements, generally refer to being within +/−8% of a target value, e.g., within +/−5% of a target value or within +/−2% of a target value, based on the context of a particular value as described herein or as known in the art. Also, the term “or” refers to an inclusive “or” and not to an exclusive “or.”

The terms “over,” “under,” “between,” and “on” as used herein refer to a relative position of one material layer or component with respect to other layers or components. For example, one layer disposed over or under another layer may be directly in contact with the other layer or may have one or more intervening layers. Moreover, one layer disposed between two layers may be directly in contact with the two layers or may have one or more intervening layers. In contrast, a first layer “on” a second layer is in direct contact with that second layer. Similarly, unless explicitly stated otherwise, one feature disposed between two features may be in direct contact with the adjacent features or may have one or more intervening layers.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C). The term “between,” when used with reference to measurement ranges, is inclusive of the ends of the measurement ranges. As used herein, the notation “A/B/C” means (A), (B), and/or (C).

The description may use the phrases “in an embodiment” or “in embodiments,” which may each refer to one or more of the same or different embodiments. Furthermore, the terms “comprising,” “including,” “having,” and the like, as used with respect to embodiments of the present disclosure, are synonymous. The disclosure may use perspective-based descriptions such as “above,” “below,” “top,” “bottom,” and “side”; such descriptions are used to facilitate the discussion and are not intended to restrict the application of disclosed embodiments. The accompanying drawings are not necessarily drawn to scale. Unless otherwise specified, the use of the ordinal adjectives “first,” “second,” and “third,” etc., to describe a common object, merely indicate that different instances of like objects are being referred to, and are not intended to imply that the objects so described must be in a given sequence, either temporally, spatially, in ranking or in any other manner.

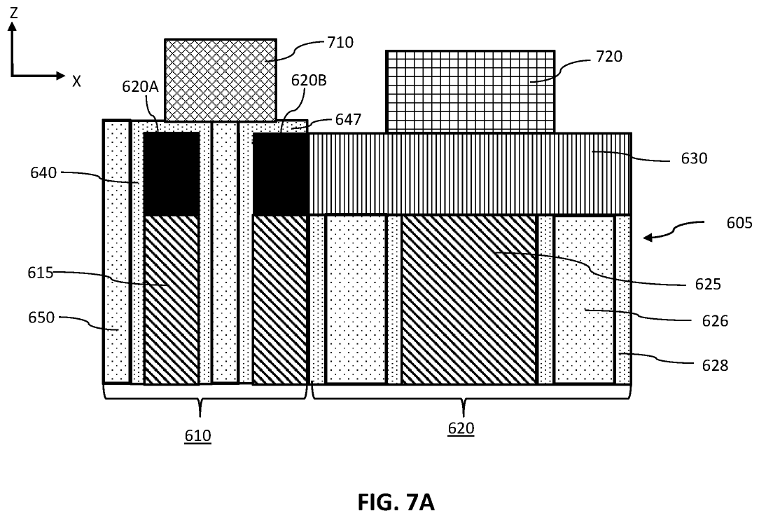

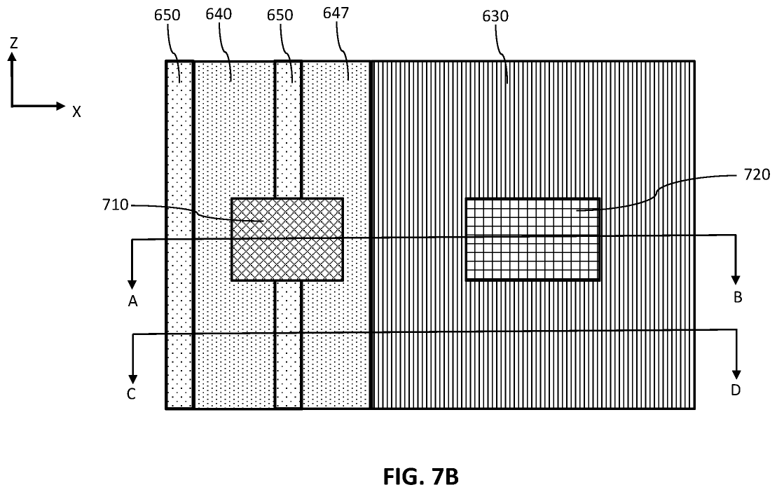

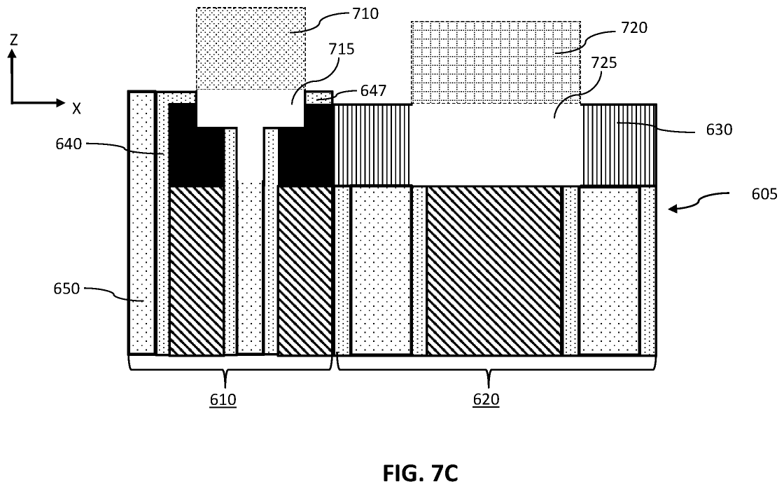

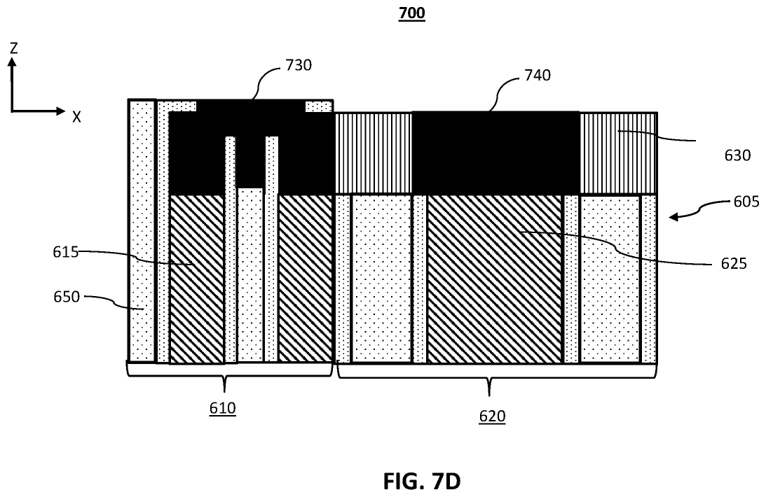

In the following detailed description, reference is made to the accompanying drawings that form a part hereof, and in which is shown, by way of illustration, embodiments that may be practiced. It is to be understood that other embodiments may be utilized and structural or logical changes may be made without departing from the scope of the present disclosure. Therefore, the following detailed description is not to be taken in a limiting sense. For convenience, if a collection of drawings designated with different letters are present, e.g., FIGS. 7A-7B, such a collection may be referred to herein without the letters, e.g., as “FIG. 7.”

In the drawings, some schematic illustrations of example structures of various devices and assemblies described herein may be shown with precise right angles and straight lines, but it is to be understood that such schematic illustrations may not reflect real-life process limitations which may cause the features to not look so “ideal” when any of the structures described herein are examined using e.g., scanning electron microscopy (SEM) images or transmission electron microscope (TEM) images. In such images of real structures, possible processing defects could also be visible, e.g., not-perfectly straight edges of materials, tapered vias or other openings, inadvertent rounding of corners or variations in thicknesses of different material layers, occasional screw, edge, or combination dislocations within the crystalline region, and/or occasional dislocation defects of single atoms or clusters of atoms. There may be other defects not listed here but that are common within the field of device fabrication. Inspection of layout and mask data and reverse engineering of parts of a device to reconstruct the circuit using e.g., optical microscopy, TEM, or SEM, and/or inspection of a cross-section of a device to detect the shape and the location of various device elements described herein using, e.g., Physical Failure Analysis (PFA) would allow determination of presence of one or more multi-pitch patterns fabricated through one or more cross-linkable copolymers as described herein.

Various operations may be described as multiple discrete actions or operations in turn in a manner that is most helpful in understanding the claimed subject matter. However, the order of description should not be construed as to imply that these operations are necessarily order dependent. In particular, these operations may not be performed in the order of presentation. Operations described may be performed in a different order from the described embodiment. Various additional operations may be performed, and/or described operations may be omitted in additional embodiments.

Various one or more multi-pitch patterns fabricated through one or more cross-linkable copolymers as described herein may be implemented in, or associated with, one or more components associated with an IC or/and may be implemented between various such components. In various embodiments, components associated with an IC include, for example, transistors, diodes, power sources, resistors, capacitors, inductors, sensors, transceivers, receivers, antennas, etc. Components associated with an IC may include those that are mounted on IC or those connected to an IC. The IC may be either analog or digital and may be used in a number of applications, such as microprocessors, optoelectronics, logic blocks, audio amplifiers, etc., depending on the components associated with the IC. The IC may be employed as part of a chipset for executing one or more related functions in a computer.

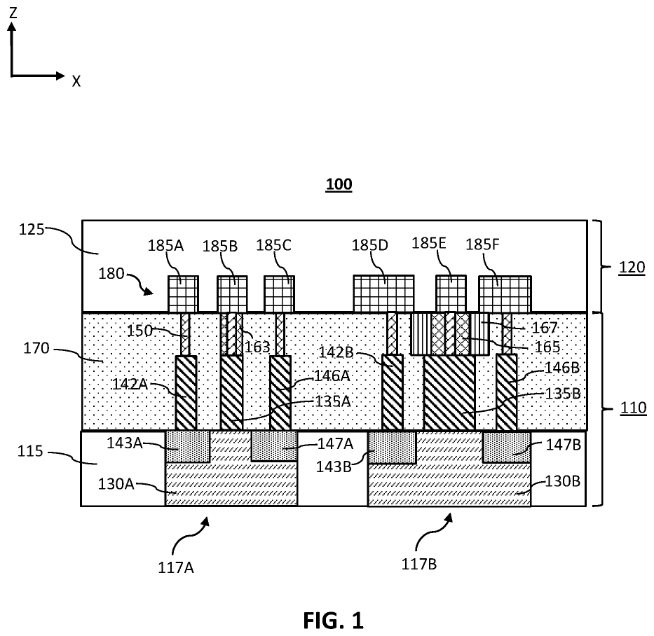

FIG. 1 illustrates an IC device 100 comprising an FEOL section 110 and a BEOL section 120, according to some embodiments of the disclosure. As shown in FIG. 1, the FEOL section 110 includes a support structure 115, two transistors 117A and 117B (collectively referred to as “transistors 117” or “transistor 117”), vias 150 (individually referred to as “via 150”), insulative structures 163, 165, and 167, and an electrical insulator 170. The BEOL section 120 includes an electrical insulator 125 and a metal layer 180 that includes metal lines 185A-185F (collectively referred to as “metal lines 185” or “metal line 185”).

In the embodiments of FIG. 1, the metal layer 180 is M0, i.e., the metal layer arranged closest to the FEOL section 110. In other embodiments, the metal layer 180 may be M1, M2, etc. Also, the IC device 100 may include fewer, more, or different components. For instance, the FEOL section 110 may include more transistors, or other semiconductor devices not shown in FIG. 1. Also, the BEOL section 120 may include one or more other metal layers, which may be coupled to at least one of the metal lines 185. The metal layer 180 may include a different number of metal lines 185, insulative spacing structures, or vias 150.

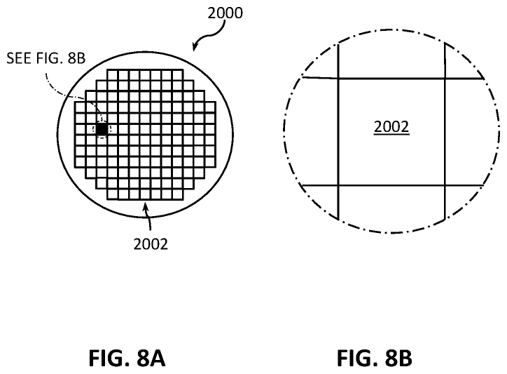

The support structure 115 may be any suitable structure, such as a substrate, a die, a wafer, or a chip, based on which the transistors 117 can be built. The support structure 115 may, e.g., be the wafer 2000 of FIG. 8A, discussed below, and may be, or be included in, a die, e.g., the singulated die 2002 of FIG. 8B, discussed below. In some embodiments, the support structure 115 may be a semiconductor substrate composed of semiconductor material systems including, for example, N-type or P-type materials systems, and, in some embodiments, the channel region 130, described herein, may be a part of the support structure 115. In some embodiments, the semiconductor substrate may be a crystalline substrate formed using a bulk silicon or a silicon-on-insulator substructure. In other embodiments, the semiconductor substrate may be formed using alternate materials, which may or may not be combined with silicon, that include but are not limited to germanium, indium antimonide, lead telluride, indium arsenide, indium phosphide, gallium arsenide, indium gallium arsenide, gallium antimonide, or other combinations of group III-V, group II-VI, or group IV materials. In some embodiments, the substrate may be non-crystalline. In some embodiments, the support structure may be a printed circuit board (PCB) substrate. One or more transistors, such as the transistors 117 may be built on the support structure 115.

Although a few examples of materials from which the support structure 115 may be formed are described here, any material that may serve as a foundation upon which an IC may be built falls within the spirit and scope of the present disclosure. In various embodiments, the support structure 115 may include any such substrate, possibly with some layers and/or devices already formed thereon, not specifically shown in the present figures. As used herein, the term “support” does not necessarily mean that it provides mechanical support for the IC devices/structures (e.g., transistors, capacitors, interconnects, and so on) built thereon. For example, some other structure (e.g., a carrier substrate or a package substrate) may provide such mechanical support and the support structure 115 may provide material “support” in that, e.g., the IC devices/structures described herein are build based on the semiconductor materials of the support structure 115. However, in some embodiments, the support structure 115 may provide mechanical support.

A transistor 117 may be a field-effect transistor (FET), such as metal-oxide-semiconductor FET (MOSFET), tunnel FET (TFET), fin-based transistor (e.g., FinFET), nanoribbon-based transistor, nanowire-based transistor, gate-all-around (GAA) transistor, other types of FET, or a combination of both. The transistor 117A includes a semiconductor structure that includes a channel region 130A, a source region 143A, and a drain region 147A. The transistor 117A includes a semiconductor structure that includes a channel region 130B, a source region 143B, and a drain region 147B. The channel regions 130A and 130B are collectively referred to as “channel regions 130” or “channel region 130.” The source regions 143A and 143B are collectively referred to as “source regions 143” or “source region 143.” The drain regions 147A and 147B are collectively referred to as “drain regions 147” or “drain region 147.”

The semiconductor structure of each transistor 117 may be at least partially in the support structure 115. The support structure 115 may include a semiconductor material, from which at least a portion of the semiconductor structure is formed. The semiconductor structure of a transistor 117 (or a portion of the semiconductor structure, e.g., the channel region 130) may be a planar structure or a non-planar structure. A non-planar structure is a three-dimensional structure, such as fin, nanowire, or nanoribbon. A non-planar structure may have a longitudinal axis and a transvers cross-section perpendicular to the longitudinal axis. In some embodiments, a dimension of the non-planar structure along the longitudinal axis may be greater than dimensions along other directions, e.g., directions along axes perpendicular to the longitudinal axis.

Each channel region 130 includes a channel material. The channel material may be composed of semiconductor material systems including, for example, n-type or p-type materials systems. In some embodiments, the channel material may include a high mobility oxide semiconductor material, such as tin oxide, antimony oxide, indium oxide, indium tin oxide, titanium oxide, zinc oxide, indium zinc oxide, gallium oxide, titanium oxynitride, ruthenium oxide, or tungsten oxide. In some embodiments, the channel material may include a compound semiconductor with a first sub-lattice of at least one element from Group III of the periodic table (e.g., Al, Ga, In), and a second sub-lattice of at least one element of group V of the periodic table (e.g., P, As, Sb). In some embodiments, the channel material may include a compound semiconductor with a first sub-lattice of at least one element from Group II of the periodic table (e.g., Zn, Cd, Hg), and a second sub-lattice of at least one element of Group IV of the periodic table (e.g., C, Si, Ge, Sn, Pb). In some embodiments, the channel material is an epitaxial semiconductor material deposited using an epitaxial deposition process. The epitaxial semiconductor material may have a polycrystalline structure with a grain size between about 2 nm and 100 nm, including all values and ranges therein.

For some example n-type transistor embodiments (i.e., for the embodiments where the transistor 117 is an NMOS (N-type metal-oxide-semiconductor) transistor or an n-type TFET), the channel material may advantageously include a III-V material having a high electron mobility, such as, but not limited to InGaAs, InP, InSb, and InAs. For some such embodiments, the channel material may be a ternary III-V alloy, such as InGaAs, GaAsSb, InAsP, or InPSb. For some InxGa1-xAs fin embodiments, In content (x) may be between 0.6 and 0.9, and may advantageously be at least 0.7 (e.g., In0.7Ga0.3As). In some embodiments with highest mobility, the channel material may be an intrinsic III-V material, i.e., a III-V semiconductor material not intentionally doped with any electrically active impurity. In alternate embodiments, a nominal impurity dopant level may be present within the channel material, for example to further fine-tune a threshold voltage Vt, or to provide HALO pocket implants, etc. Even for impurity-doped embodiments however, impurity dopant level within the channel material 304 may be relatively low, for example below 10¹⁵ dopant atoms per cubic centimeter (cm-3), and advantageously below 10¹³ cm⁻³. These materials may be amorphous or polycrystalline, e.g., having a crystal grain size between 0.5 nanometers and 100 nanometers.

For some example p-type transistor embodiments (i.e., for the embodiments where the transistor 117 is a PMOS (P-type metal-oxide-semiconductor) transistor or a p-type TFET), the channel material may advantageously be a Group IV material having a high hole mobility, such as, but not limited to Ge or a Ge-rich SiGe alloy. For some example embodiments, the channel material may have a Ge content between 0.6 and 0.9, and advantageously may be at least 0.7. In some embodiments with highest mobility, the channel material may be intrinsic III-V (or IV for P-type devices) material and not intentionally doped with any electrically active impurity. In alternate embodiments, one or more a nominal impurity dopant level may be present within the channel material, for example to further set a threshold voltage (Vt), or to provide HALO pocket implants, etc. Even for impurity-doped embodiments however, impurity dopant level within the channel portion is relatively low, for example below 10¹⁵ cm⁻³, and advantageously below 10¹³ cm⁻³. These materials may be amorphous or polycrystalline, e.g., having a crystal grain size between 0.5 nanometers and 100 nanometers.

In some embodiments, the channel material may include a high mobility oxide semiconductor material, such as tin oxide, antimony oxide, indium oxide, indium tin oxide, titanium oxide, zinc oxide, indium zinc oxide, indium gallium zinc oxide (IGZO), gallium oxide, titanium oxynitride, ruthenium oxide, aluminum zinc oxide, or tungsten oxide. In general, for a thin-film transistor (TFT), the channel material may include one or more of tin oxide, cobalt oxide, copper oxide, antimony oxide, ruthenium oxide, tungsten oxide, zinc oxide, gallium oxide, titanium oxide, indium oxide, titanium oxynitride, indium tin oxide, indium zinc oxide, nickel oxide, niobium oxide, copper peroxide, IGZO, indium telluride, molybdenite, molybdenum diselenide, tungsten diselenide, tungsten disulfide, molybdenum disulfide, N- or P-type amorphous or polycrystalline silicon, monocrystalline silicon, germanium, indium arsenide, indium gallium arsenide, indium selenide, indium antimonide, zinc antimonide, antimony selenide, silicon germanium, gallium nitride, aluminum gallium nitride, indium phosphite, black phosphorus, zinc sulfide, indium sulfide, gallium sulfide, each of which may possibly be doped with one or more of gallium, indium, aluminum, fluorine, boron, phosphorus, arsenic, nitrogen, tantalum, tungsten, and magnesium, etc. In some embodiments, a thin-film channel material may be deposited at relatively low temperatures, which allows depositing the channel material within the thermal budgets imposed on back-end fabrication to avoid damaging other components, e.g., front end components such as logic devices.

As noted above, the channel material may include IGZO. IGZO-based devices have several desirable electrical and manufacturing properties. IGZO has high electron mobility compared to other semiconductors, e.g., in the range of 20-50 times than amorphous silicon. Furthermore, amorphous IGZO (a-IGZO) transistors are typically characterized by high band gaps, low-temperature process compatibility, and low fabrication cost relative to other semiconductors.

IGZO can be deposited as a uniform amorphous phase while retaining higher carrier mobility than oxide semiconductors such as zinc oxide. Different formulations of IGZO include different ratios of indium oxide, gallium oxide, and zinc oxide. One particular form of IGZO has the chemical formula InGaO₃(ZnO)₅. Another example form of IGZO has an indium:gallium:zinc ratio of 1:2:1. In various other examples, IGZO may have a gallium to indium ratio of 1:1, a gallium to indium ratio greater than 1 (e.g., 2:1, 3:1, 4:1, 5:1, 6:1, 7:1, 8:1, 9:1, or 10:1), and/or a gallium to indium ratio less than 1 (e.g., 1:2, 1:3, 1:4, 1:5, 1:6, 1:7, 1:8, 1:9, or 1:10). IGZO can also contain tertiary dopants such as aluminum or nitrogen.

In each transistor 117, the source region 143 and the drain region 147 are connected to the channel region 130. The source region 143 and the drain region 147 each includes a semiconductor material with dopants. In some embodiments, the source region 143 and the drain region 147 have the same semiconductor material, which may be the same as the channel material of the channel region 130. A semiconductor material of the source region 143 or the drain region 147 may be a Group IV material, a compound of Group IV materials, a Group III/V material, a compound of Group III/V materials, a Group II/VI material, a compound of Group II/VI materials, or other semiconductor materials. Example Group II materials include zinc (Zn), cadmium (Cd), and so on. Example Group III materials include aluminum (Al), boron (B), indium (In), gallium (Ga), and so on. Example Group IV materials include silicon (Si), germanium (Ge), carbon (C), etc. Example Group V materials include nitrogen (N), phosphorus (P), arsenic (As), antimony (Sb), and so on. Example Group VI materials include sulfur (S), selenium (Se), tellurium (Te), oxygen (O), and so on. A compound of Group IV materials can be a binary compound, such as SiC, SiGe, and so on. A compound of Group III/V materials can be a binary, tertiary, or quaternary compound, such as GaN, InN, and so on. A compound of Group II/VI materials can be a binary, tertiary, or quaternary compounds, such as CdSe, CdS, CdTe, ZnO, ZnSe, ZnS, ZnTe, CdZnTe, CZT, HgCdTe, HgZnTe, and so on.

In some embodiments, the dopants in the source region 143 and the drain region 147 are the same type. In other embodiments, the dopants of the source region 143 and the drain region 147 may be different (e.g., opposite) types. In an example, the source region 143 has n-type dopants and the drain region 147 has p-type dopants. In another example, the source region 143 has p-type dopants and the drain region 147 has n-type dopants. Example n-type dopants include Te, S, As, tin (Sn), Si, Ga, Se, S, In, Al, Cd, chlorine (CI), iodine (I), fluorine (F), and so on. Example p-type dopants include beryllium (Be), Zn, magnesium (Mg), Sn, P, Te, lithium (Li), sodium (Na), Ga, Cd, and so on.

In some embodiments, the source region 143 and the drain region 147 may be highly doped, e.g., with dopant concentrations of about 1.1021 cm-3, in order to advantageously form Ohmic contacts with the respective S/D contacts (also sometimes interchangeably referred to as “S/D electrodes”), although these regions may also have lower dopant concentrations and may form Schottky contacts in some implementations. Irrespective of the exact doping levels, the source region 143 and the drain region 147 may be the regions having dopant concentration higher than in other regions, e.g., higher than a dopant concentration in the channel region 130, and, therefore, may be referred to as “highly doped” (HD) regions.

The channel region 130 may include one or more semiconductor materials with doping concentrations significantly smaller than those of the source region 143 and the drain region 147. For example, in some embodiments, the channel material of the channel region 130 may be an intrinsic (e.g., undoped) semiconductor material or alloy, not intentionally doped with any electrically active impurity. In alternate embodiments, nominal impurity dopant levels may be present within the channel material, for example to set a threshold voltage Vt, or to provide HALO pocket implants, etc. In such impurity-doped embodiments however, impurity dopant level within the channel material is still significantly lower than the dopant level in the source region 143 and the drain region 147, for example below 10¹⁵ cm⁻³ or below 10¹³ cm⁻³. Depending on the context, the term “S/D terminal” may refer to a S/D region or a S/D contact or electrode of a transistor.

The transistor 117A also includes a source contact 142A over the source region 143A and a drain contact 146A over the drain region 147A. The transistor 117B also includes a source contact 142B over the source region 143B and a drain contact 146B over the drain region 147B. The source contacts 142A and 142B are collectively referred to as “source contacts 142” or “source contact 142.” The drain contacts 146A and 146B are collectively referred to as “drain contacts 146” or “drain contact 146.” The source contacts 142 and the drain contacts 146 are electrically conductive and may be coupled to source and drain terminals for receiving electrical signals. A source contact 142 or the drain contact 146 includes one or more electrically conductive materials, such as metals. Examples of metals in the source contacts 142 and the drain contacts 146 may include, but are not limited to, Ruthenium (Ru), copper (Cu), cobalt (Co), palladium (Pd), platinum (Pt), nickel (Ni), and so on.

Each transistor 117 also includes a gate that is over or wraps around at least a portion of the channel region 130. The gate of the transistor 117A includes a gate contact 135A. The gate of the transistor 117B includes a gate contact 135B. The gate contacts 135A and 135B are collectively referred to as “gate contacts 135” or “gate contact 135.” The gate contact 135A has a smaller length along the X axis than the gate contact 135B. In an example, the length of the gate contact 135A may be about half of the length of the gate contact 135B. In some embodiments, the source contacts 142 or drain contacts 146 may have the same or similar length along the X axis as the gate contact 135A. In other embodiments, the source contacts 142 or drain contacts 146 may have the same or similar length along the X axis as the gate contact 135B. In some embodiments, the source contacts 142 may have different lengths from each other. The drain contacts 146 may have different lengths from each other.

In each transistor 117, the gate contact 135 can be coupled to a gate terminal that controls gate voltages applied on the transistor 117. The gate contact 135 may include one or more gate electrode materials, where the choice of the gate electrode materials may depend on whether the transistor 117 is a p-type transistor or an n-type transistor. For a p-type transistor, gate electrode materials that may be used in different portions of the gate electrode may include, but are not limited to, Ru, Pd, Pt, Co, Ni, and conductive metal oxides (e.g., ruthenium oxide). For an n-type transistor, gate electrode materials that may be used in different portions of the gate electrode, but are not limited to, hafnium, zirconium, titanium, tantalum, aluminum, alloys of these metals, and carbides of these metals (e.g., hafnium carbide, zirconium carbide, titanium carbide, tantalum carbide, and aluminum carbide). In some embodiments, the gate contact 135 may include a stack of a plurality of gate electrode materials, where zero or more materials of the stack are workfunction (WF) materials and at least one material of the stack is a fill metal layer. Further materials/layers may be included next to the gate electrode for other purposes, such as to act as a diffusion barrier layer or/and an adhesion layer.

The gate of a transistor 117 may also include a gate insulator (not show in FIG. 1) that separates at least a portion of the channel region 130 from the gate electrode so that the channel region 130 is insulated from the gate electrode. In some embodiments, the gate insulator may wrap around at least a portion of the channel region 130. The gate insulator may also wrap around at least a portion of the source region 143 or the drain region 147. At least a portion of the gate insulator may be wrapped around by the gate electrode. The gate insulator includes an electrical insulator, such as a dielectric material, hysteretic material, and so on. Example dielectric material includes oxide (e.g., Si based oxides, metal oxides, etc.), high-k dielectric, and so on. Example hysteretic material include ferroelectric materials, antiferroelectric materials, etc.

As shown in FIG. 1, the transistors 117 are coupled to the metal layer 180 through the vias 150. The metal layer 180 may facilitate controlling operation of the transistors 117 by providing electrical signals to the transistors 117, such as the source contacts 142, the drain contacts 146, or the gate contacts 135. For purpose of illustration, the metal lines 185A and 185D are coupled to the source contacts 142, the metal lines 185B and 185E are coupled to the gate contacts 135, and the metal lines 185C and 185F are coupled to the drain contacts 146. Each metal line 185 is an electrically conductive structure. A metal line 185 may also be referred to as electrically conductive interconnects or interconnects. The metal layer 180 may also be referred to as an electrically conductive interconnect set or an interconnect set. In some embodiments, a metal line 185 includes one or more metal, such as tungsten (W), molybdenum (Mo), ruthenium (Ru), copper (Cu), other metals, or some combination thereof. The metal lines 185 are shown as rectangles in FIG. 1 for purpose of illustration. The metal lines 185 may have different shapes in other embodiments. Some or all of the metal lines 185 may be at different electrical potentials during operation of the IC device 100. The metal lines 185 are arranged in parallel in FIG. 1. A metal line 185 may have a longitudinal axis along the Y axis. The metal line 185 may have a transvers cross-section perpendicular to the longitudinal axis. In some embodiments, the metal lines 185 have the same or similar height, i.e., the dimension along the Z axis.

The metal lines 185 are insulated from each other by the electrical insulator 125. The electrical insulator 125 includes one or more electrically insulative materials. An electrically insulative material may be a dielectric material, hysteretic material, and so on. Example dielectric material includes oxide (e.g., Si based oxides, metal oxides, etc.), nitride (e.g., Si based nitride, etc.), low-k dielectric, high-k dielectric, and so on. Example hysteretic material include ferroelectric materials, antiferroelectric materials, and so on. The electrical insulator 125 may be referred to as ILD of the BEOL section 120.

The vias 150 can provide a conductive channel between the transistors 117 and the metal layer 180. Each via 150 has an end that is connected to a gate contact 135, source contact 142, or drain contact 146. The other end of the via 150 is connected to a metal line 180. Each via 150 is electrically conductive. A via 150 may include a metal, such as tungsten (W), molybdenum (Mo), ruthenium (Ru), copper (Cu), or other metals. Different vias 150 may include different materials. The vias 150 that are connected to gate contacts may be referred to as VCGs. The vias 150 that are connected to source contacts and drain contacts may be referred to as VCTs. For purpose of illustration, FIG. 1 shows two vias 150 (i.e., the vias that are connected to the metal lines 185B and 185E) that are VCGs and four vias 150(i.e., the vias that are connected to the metal lines 185 A, 185C, 185D, and 185F) that are VCTs. In other embodiments, the transistors 117 may be coupled to the metal layer 180 through a different number of vias 150. In other embodiments, the electrical connection between the metal layer 180 and the transistors 117 may be different. Also, the transistors 117 may be coupled to one or more other metal layers. Even though not shown in FIG. 1, the metal layer 180 may be coupled with other devices than the transistor 117, such as diodes, power sources, resistors, capacitors, inductors, sensors, transceivers, receivers, antennas, and so on.

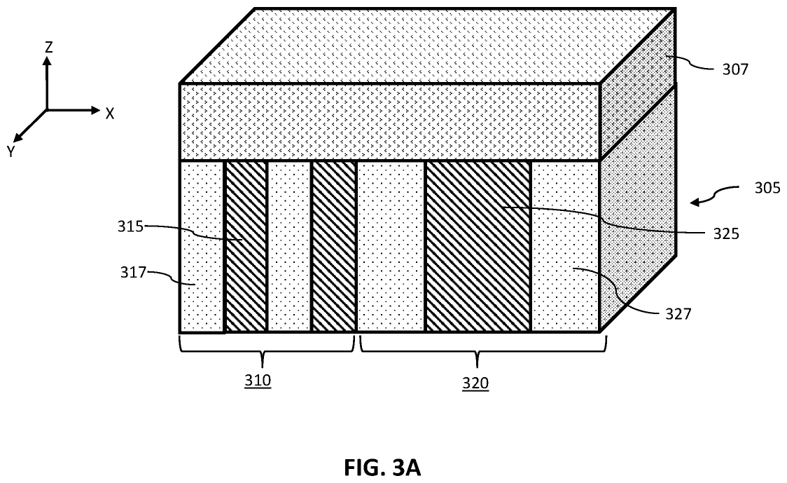

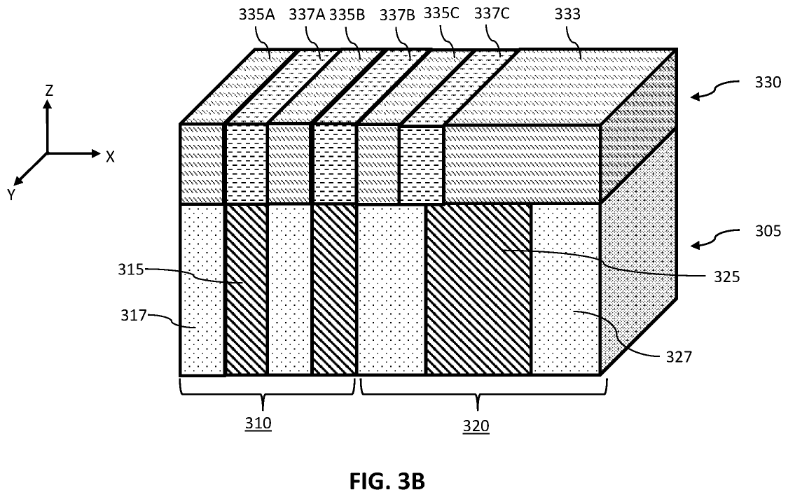

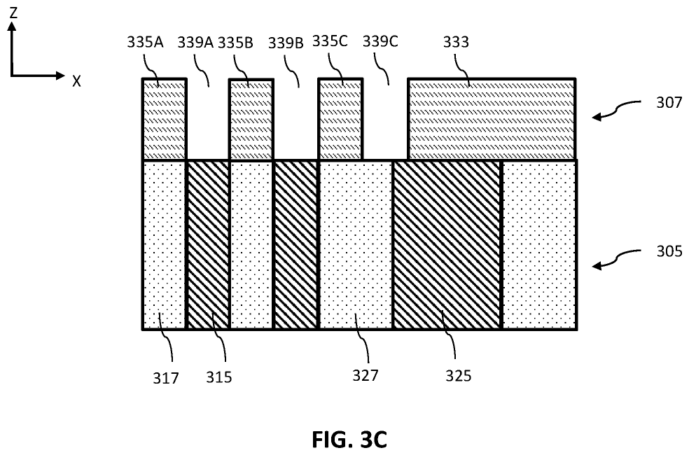

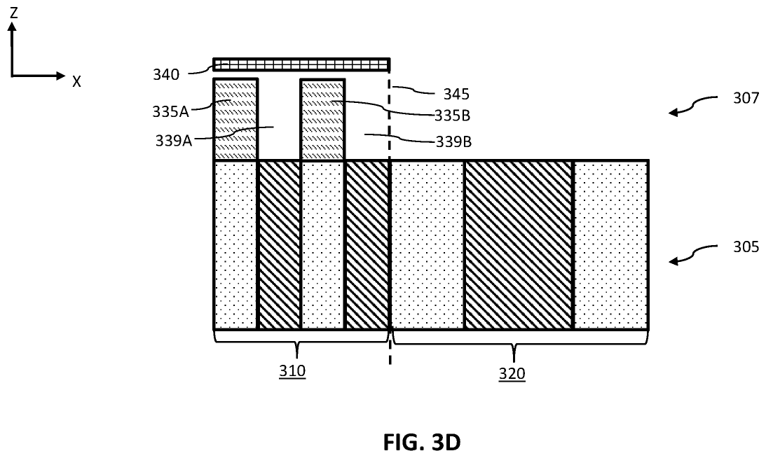

The vias 150 or metal lines 185 may be formed through patterning over an underlayer that includes the gate contacts 135, source contacts 142, and drain contacts 146. As shown in FIG. 1, the gate contacts 135 have different lengths along the X axis: the gate contact 135B has a greater length than the gate contact 135A. Thus, the underlayer has two different pitches, which causes challenges to pattern based on the DSA of a block copolymer as the DSA typically has one fixed pitch. In some embodiments, the patterning over the underlayer may be through a one-step flow, such as the one-step flow described below in conjunction with FIGS. 3A-3D, 4A-4D, 5A-5C, 6A-6D, and 7A-7D. Through the one-step flow, the insulative structure 163 is formed in association with the gate contact 135A, and the insulative structures 165 and 167 are formed in association with the gate contact 135B

In the embodiments of FIG. 1, the insulative structure 163 is over the gate contact 135A. The insulative structure 165 is over with the gate contact 135B. The insulative structure 167 at least partially wraps around the insulative structure 165. In some embodiments, the insulative structure 163 may include a same dielectric material (such as nitride, e.g., silicon nitride, etc.) as the insulative structure 165. The insulative structure 167 may include a different dielectric material (such as oxide, e.g., silicon oxide, etc.) from the insulative structures 163 and 165. The insulative structure 167 may function as a guard ring of the gate contact 135B.

In some embodiments, the via 150 connected to the gate contact 135A may be formed by forming an opening in the insulative structure 163 and filling the opening with one or more conductive materials. Similarly, the via 150 connected to the gate contact 135B may be formed by forming an opening in the insulative structure 165 and filling the opening with one or more conductive materials. Even though the vias 150 connected to the gate contacts 135 are at least partially surrounded by the insulative structures 163 and 165, respectively and have smaller lengths than the gate contacts 135 along the X axis in FIG. 1, the vias 150 may have the same or similar lengths as the gate contacts 135 in other embodiments. The via 150 connected to the gate contact 135A may contact the electrical insulator 170. The via 150 connected to the gate contact 135B may contact the insulative structure 167.

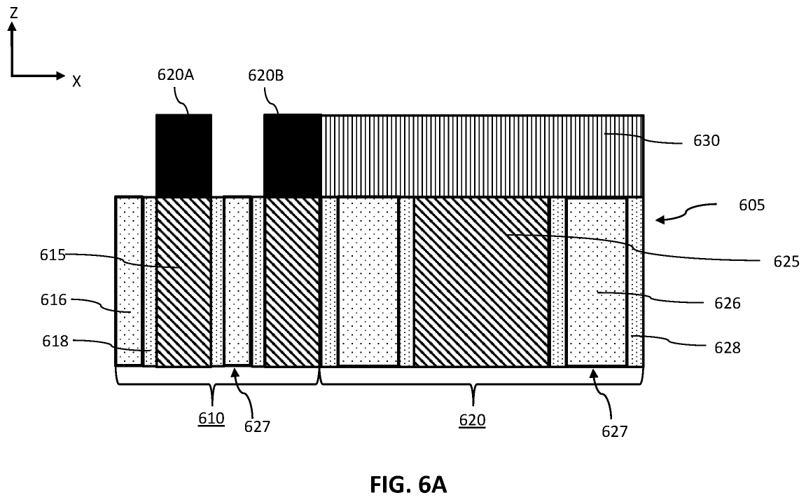

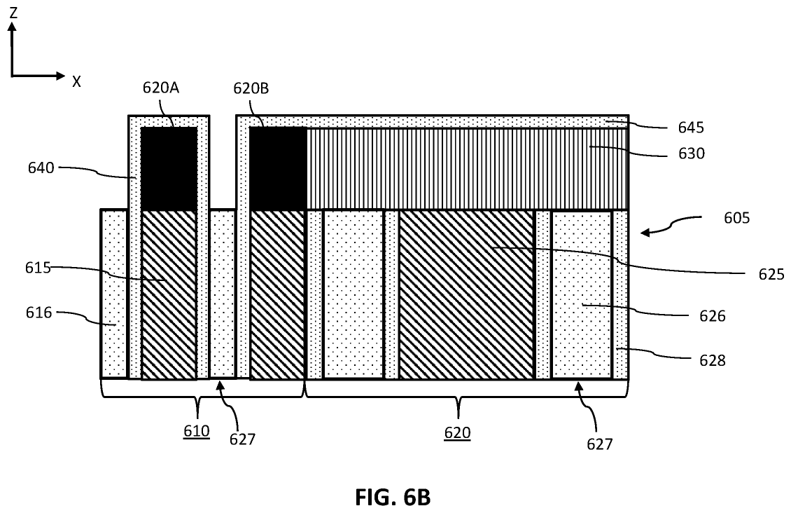

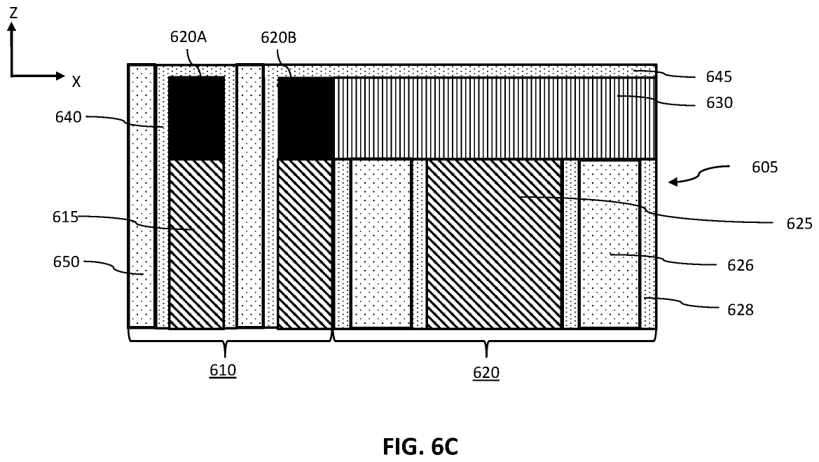

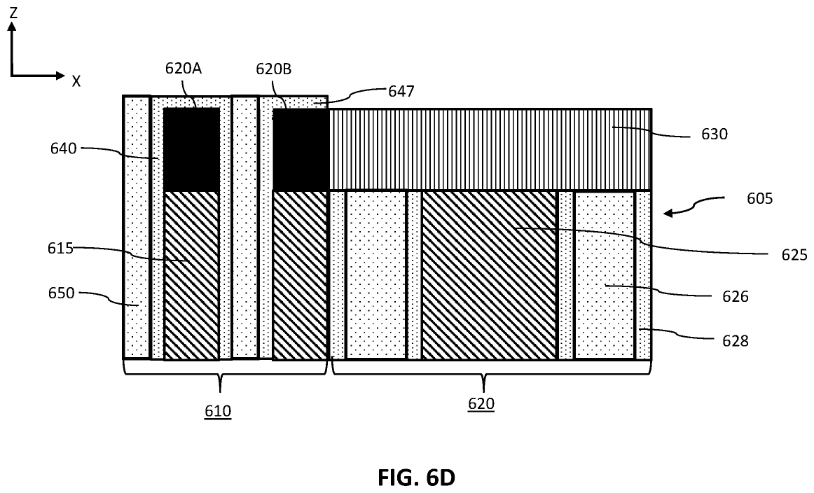

The electrical insulator 170 includes one or more electrically insulative materials. An electrically insulative material may be a dielectric material, hysteretic material, and so on. Example dielectric material includes oxide (e.g., Si based oxides, metal oxides, etc.), nitride (e.g., Si based nitride, etc.), low-k dielectric, high-k dielectric, and so on. Example hysteretic material include ferroelectric materials, antiferroelectric materials, and so on. In some embodiments, a portion of the electrical insulator 170 may include a first electrical insulator and a second electrical insulator with the second electrical insulator at least partially surrounding the first electrical insulator. An example of the first electrical insulator may be the insulative structure 626 in FIGS. 6A-6D. An example of the second electrical insulator may be the insulative structure 628 in FIGS. 6A-6D.

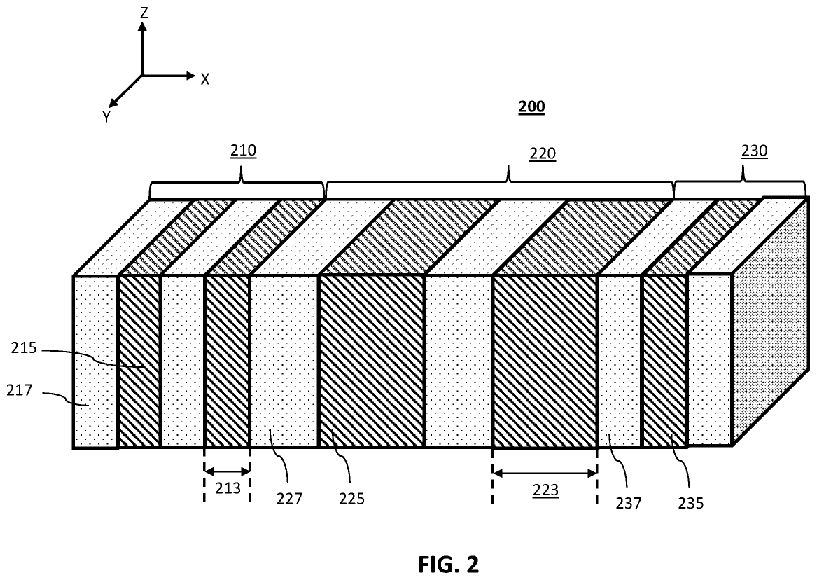

FIG. 2 illustrates a multi-pitch layer 200, according to some embodiments of the disclosure. The multi-pitch layer 200 may be an embodiment of the underlayer including the gate contacts 135 or the metal layer 180 in FIG. 1. As shown in FIG. 2, the multi-pitch layer 200 includes a tight pitch region 210, a loose pitch region 220, and another tight pitch region 230. In other embodiments, the multi-pitch layer 200 may include fewer, more or different regions.

The tight pitch region 210 include conductive structures 215 (individually referred to as “conductive structure 215”) and insulative structures 217 (individually referred to as “insulative structure 217”). The conductive structures 215 have longitudinal axes along the Z axis. Two adjacent conductive structures 215 are separated by an insulative structure 217. A pitch 213 of the conductive structures 215 is a length of a conductive structure 215 along the X axis. An example of the conductive structure 215 may be the gate contact 135A in FIG. 1.

The loose pitch region 220 include conductive structures 225 (individually referred to as “conductive structure 225”) and insulative structures 227 (individually referred to as “insulative structure 227”). The conductive structures 225 have longitudinal axes along the Z axis. Two adjacent conductive structures 225 are separated by an insulative structure 227. In some embodiments, the loose pitch region 220 has a pitch 223, which is a length of a conductive structure 225 along the X axis. The pitch 223 is greater than the pitch 213 of the tight pitch region 210. An example of the conductive structure 225 may be the gate contact 135B in FIG. 1.

The tight pitch region 230 include a conductive structure 235 and insulative structures 237 (individually referred to as “insulative structure 237”). The conductive structure 235 has a longitudinal axis along the Z axis. The conductive structure 235 is separated by a conductive structure 225 in the loose pitch region 220 by an insulative structure 227. For purpose of illustration, FIG. 2 shows one conductive structure 235 in the tight pitch region 230. In other embodiments, the tight pitch region 230 may include more conductive structures 235. A pitch of the conductive structure 235 in the tight pitch region 230 may be the same or similar as the pitch 223 of the tight pitch region 210. An example of the conductive structure 235 may be the gate contact 135A in FIG. 1.

An insulative structure 217, 227, or 237 may include a first insulative structure and a second insulative structure. The first insulative structure may be a layer of an electrical insulator that at least partially surrounds the second insulative structure. In some embodiments, the first insulative structure and the second insulative structure may include different insulators. In an example, the first insulative structure may include a nitride, such as silicon nitride, and the second insulative structure may include an oxide, such as silicon oxide.

Due to the differences in the pitches 213 and 223, the multi-pitch layer 200 has a multi-pitch pitch pattern, which causes challenges to pattern over the multi-pitch layer 200 through DSA of block copolymers, as DSA of block copolymer is usually limited to single pitch pattern. The single pitch pattern may be defined by an average molecular weight of the block copolymer. In an example, the average molecular weight block copolymer may be compatible with the pitch pattern of the tight pitch region 210 or 230 so that the conductive structure-insulative structure alternating pattern in the tight pitch region 210 or 230 may function as a guiding pattern for the DSA of the block copolymer. Lamellar structures formed through the self-assembly of the block copolymer can align with the conductive structure and insulative structures in the tight pitch regions 210 and 230.

However, given that the loose pitch region 220 has a different pitch pattern, the average molecular weight block copolymer is incompatible with the pitch pattern of the loose pitch region 220. Lamellar structures would fail to align with the conductive structure 225 or insulative structures 227 in the loose pitch region 220. This can result in undesired DSA single pitch, random fingerprint pattern, horizontal morphology, or some combination thereof over the loose pitch region 220. These undesired patterns formed over the loose pitch region 220 need to be removed, e.g., through cut mask.

FIGS. 3A-3D illustrate multi-pitch patterning through DSA of a block copolymer and a cut mask 340, according to some embodiments of the disclosure. FIG. 3A shows a multi-pitch layer 305. The multi-pitch layer 305 may be an embodiment of a portion of the multi-pitch layer 200 in FIG. 2. The multi-pitch layer 305 includes a tight pitch region 310 and a loose pitch region 320. The tight pitch region 310 may be an embodiment of the tight pitch region 210 or 230 in FIG. 2. The loose pitch region 320 may be an embodiment of the loose pitch region 220 in FIG. 2. In other embodiments, the multi-pitch layer 305 may include more or different regions. For instance, the multi-pitch layer 305 may include another active region arranged at the opposite side of the loose pitch region 320 from the tight pitch region 310.

As shown in FIG. 3A, the tight pitch region 310 include conductive structures 315 (individually referred to as “conductive structure 315”) and insulative structures 317 (individually referred to as “insulative structure 317”). The conductive structures 315 alternative with the insulative structures 317. The conductive structures 315 have longitudinal axes along the Z axis. Two adjacent conductive structures 315 are separated and insulated by an insulative structure 317. The conductive structures 315 may include one or more metals, such as Co, Al, Cu, Al-doped Cu, Ru, Mo, Ti, W, and so on. The insulative structures 317 may include one or more electrical insulators. An electrical insulator may be a dielectric material, hysteretic material, and so on. The dielectric material may be low-k dielectric, high-k dielectric, and so on. Examples of the dielectric material include silicon oxides, doped silicon oxides, fluorinated silicon oxides, carbon doped oxides, metal oxide (e.g., alumina, etc.), carbon nitride, carbide, and so on. The hysteretic material may be ferroelectric materials, antiferroelectric materials, and so on.

The loose pitch region 320 include a conductive structure 325 and insulative structures 327 (individually referred to as “insulative structure 327”). The conductive structure 325 is separated from a conductive structure 315 (i.e., the conductive structure 315 that is closest to the conductive structure 325) by an insulative structure 327 (i.e., the insulative structure 327 between the conductive structure 315 and the conductive structure 325). Even though FIG. 3A shows one conductive structure 325 in the transition region, the loose pitch region 320 may include multiple conductive structures 325, which may be separated by insulative structures 327 that alternate with the conductive structures 325. The loose pitch region 320 has a larger pitch than the tight pitch region 310.

A layer 307 is formed over the multi-pitch layer 305. The layer 307 includes a diblock copolymer. The diblock copolymer may include two polymers: polymer A and polymer B. A molecule of the diblock copolymer may include a block of polymer A and a block of polymer B. A chain of the diblock copolymer has a repetitive pattern of blocks of polymer A alternating with blocks of polymer B. An individual block of polymer A includes predominantly a chain of covalently linked monomer A (e.g., A-A-A-A-A . . . ), whereas the block of polymer B includes predominantly a chain of covalently linked monomer B (e.g., B-B-B-B-B . . . ). The monomers A and B may represent any of the different types of monomers used in block copolymers known in the arts. Examples of the polymer A and polymer B include polyethylene, poly(methyl methacrylate), polystyrene, polyvinylchloride, polytetrafluorethylene, polydimethylsiloxane, some polyesters, some polyurethanes, acrylics, epoxies, P(t-Buytl Acrylate), polyacrylic acid, polyacrylamide, maleic anhydride polymers, polyethylene, polypropylene, polyacrylonitrile, polybutadiene, polyvinyl acetate, polyacetic acid, polybutyl acrylate, polylactic acid, polycaprolactone, poly(ethylene glycol), polyisoprene, and so on. In other embodiments, the polymer A or polymer B may be other polymers.

In some embodiments, the block of polymer A and the block of polymer B have different chemical properties. As one example, one of the blocks may be relatively more hydrophobic (e.g., water disliking) and the other may be relatively more hydrophilic (water liking). As another example, one of the blocks may be relatively more similar to oil and the other block may be relatively more similar to water. Such differences in chemical properties between the different blocks of polymers, whether a hydrophilic-hydrophobic difference or otherwise, may cause the diblock copolymer molecule to self-assemble. For example, the self-assembly may be based on microphase separation of the polymer blocks. Conceptually, this may be similar to the phase separation of oil and water which are generally immiscible. Similarly, differences in hydrophilicity between the polymer blocks (e.g., one block is relatively hydrophobic and the other block is relatively hydrophilic), may cause a roughly analogous microphase separation where the different polymer blocks try to separate from each other due to chemical dislike for the other.

However, because the polymer blocks are covalently bonded to one another, they cannot be completely separated on a macroscopic scale. Rather, polymer blocks of a given type may tend to segregate or conglomerate with polymer blocks of the same type of other molecules. Self-assembly of the diblock copolymer, whether based on hydrophobic-hydrophilic differences or otherwise, may be used to form extremely small periodic structures (e.g., precisely spaced nanoscale structures). In some embodiments, the diblock copolymer can be used to form lamellar structures based on which patterning of metal lines, vias, or other components of IC devices may be performed. The dimensions of the lamellar structures are dependent upon the molecular weight, the lengths of the polymer blocks, and so on.

In FIG. 3B, a DSA layer 330 is formed over the multi-pitch layer 305 through DSA of the diblock copolymer in the layer 307. The DSA layer 330 includes lamellar structures 335A-335C (collectively referred to as “lamellar structures 335” or “lamellar structure 335”), lamellar structures 337A-337C (collectively referred to as “lamellar structures 337” or “lamellar structure 337”), and a lamellar structure 333. In some embodiments, the lamellar structures 335 and the lamellar structure 333 includes one of the polymers in the diblock copolymer, and the lamellar structures 337 includes the other polymer in the diblock copolymer. Individual lamellar structures 335 alternative with individual lamellar structures 337, which constitutes a single pitch DSA pattern. The pitch of the DSA pattern is a center-to-center distance between two adjacent lamellar structures 335 or two adjacent lamellar structures 337.

The pitch of the DSA pattern may be the same or similar as the metal pitch of the tight pitch region 310 but is different from the metal pitch of the loose pitch region 320. Given the difference from the metal pitch of the loose pitch region 320, the DSA pattern cannot be formed over the whole loose pitch region 320. As shown in FIG. 3B, the single pitch DSA pattern is formed over a portion of the loose pitch region 320 (i.e., the portion over which the lamellar structures 335C and 337C are formed). The rest of the loose pitch region 320 does not have the DSA pattern. Rather, the lamellar structure 333 is formed over the rest of the loose pitch region 320.

The formation of the lamellar structures 335 and 337 may be facilitated by the alternating pattern of the conductive structures 315 and insulative structures 317. In some embodiments, the alternating pattern of the conductive structures 315 and insulative structures 317 may constitute a guiding pattern for the DSA of the diblock copolymer. For instance, polymer A in the diblock copolymer may have stronger chemical affinity with the material in the conductive structures 315 than the material in the insulative structures 317. Additionally or alternatively, polymer B in the diblock copolymer may have stronger chemical affinity with the material in the conductive structures 315 than the material in the insulative structures 317. As a result, the lamellar structures 335, which includes polymer A, are formed over the insulative structures 317, and the lamellar structures 335, which includes polymer B, are formed over the conductive structures 315.

In other embodiments, a guiding pattern may be formed over at least part of the multi-pitch layer 305 before the layer 307 is formed. The guiding pattern may include a surface treatment. For instance, polymers may be grated to the multi-pitch layer 305, e.g., by using end groups. Examples of the end groups include polyethylene, poly(methyl methacrylate), polystyrene, polyvinylchloride, polytetrafluorethylene, polydimethylsiloxane, some polyesters, some polyurethanes, acrylics, epoxies, P(t-Buytl Acrylate), polyacrylic acid, polyacrylamide, maleic anhydride polymers, polyethylene, polypropylene, polyacrylonitrile, polybutadiene, polyvinyl acetate, polyacetic acid, polybutyl acrylate, polylactic acid, polycaprolactone, poly(ethylene glycol), polyisoprene, and so on. Polymers may be grafted selectively to the top surfaces of the conductive structures 315 or the top surfaces of insulative structures 317. The surface treatment may change the chemical affinity of polymer A or polymer B with the conductive structures 315 or the insulative structures 317.

In some embodiments, polymer A and polymer B have different mechanical properties. For example, polymer A are more rigid than polymer B. Accordingly, the lamellar structures 335 are more rigid than the lamellar structures 337. In an embodiment, the lamellar structures 335 has a rigidity above a first threshold and the lamellar structures 337 has a rigidity below a second threshold that is lower than the first threshold. As polymer B is more flexible, the block of polymer B may be more easily stretched or compressed between the blocks of polymer A when the diblock copolymer forms the lamellar structures 335 and 337. In an embodiment, a block of polymer B folds onto itself during the self-assembly of the diblock copolymer molecule. The higher rigidity of the lamellar structures 335 helps ensure a uniform size of the lamellar structures 337 and consequently, help ensure a single pitch of the DSA pattern. Also, as the lamellar structures 337 is relatively flexible, the lamellar structures 337 can be removed through an etching process that does not or barely etch the lamellar structures 335.

In FIG. 3C, the lamellar structures 337 are removed and forms openings 339A-339C (collectively referred to as “openings 339” or “openings 339”). FIG. 3C shows a cross-sectional view in the X-Z plane. In some embodiments, the lamellar structures 337 may be removed through etching. The lamellar structures 335 and 333, which is more rigid than the lamellar structures 337 may be barely etched or not etched at all. But given the multi-pitch pattern in the multi-pitch layer 305, the removal of the lamellar structures 337 is not sufficient. The lamellar structures 335C and 333 need to be removed too since they do not match the pitch pattern of the loose pitch region 320 and cannot be used for patterning over the loose pitch region 320.

In FIG. 3D, the lamellar structures 335C and 333, which includes the more rigid polymer in the diblock copolymer, are removed. The lamellar structures 335A and 335B need to be reserved for patterning over the tight pitch region 310. The removal of the lamellar structures 335C and 333 is done by using a cut mask 340. The cut mask 340 is over the tight pitch region 310. An edge of the cut mask 340 is aligned (e.g., overlaps), along the Z axis, with an edge 345 of the tight pitch region 310 where the tight pitch region 310 contacts with the loose pitch region 320. The cut mask 340 may be placed over the lamellar structures 335A and 335B and prevents the lamellar structures 335A and 335B from being removed in the process of removing the lamellar structures 335C and 333.

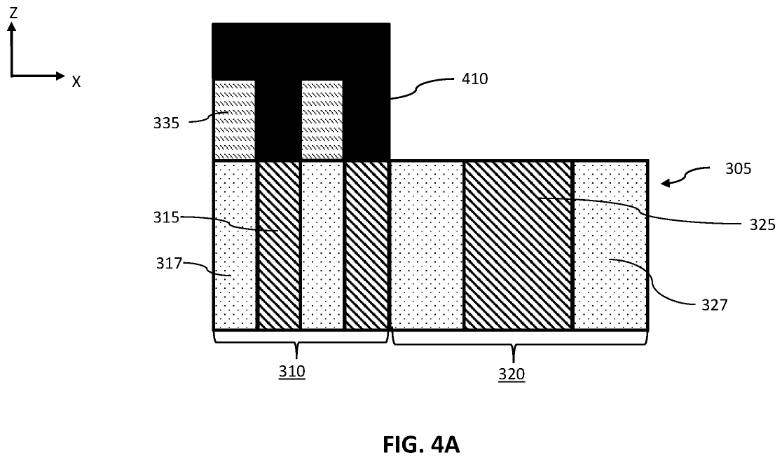

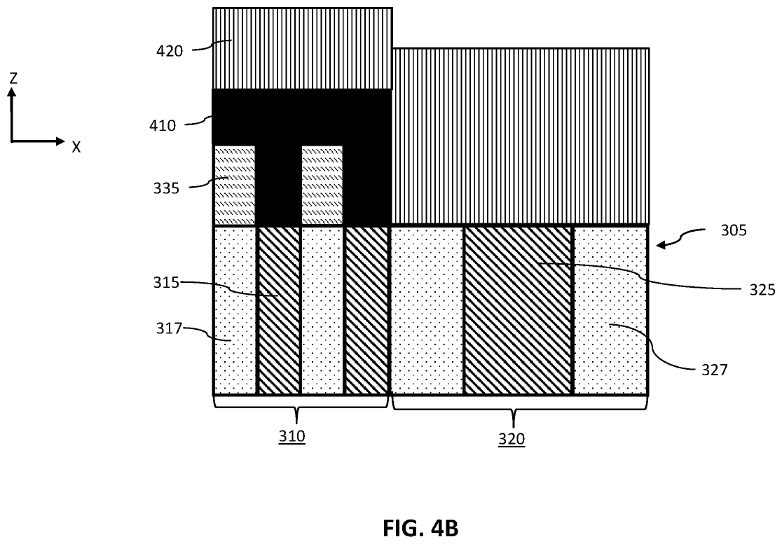

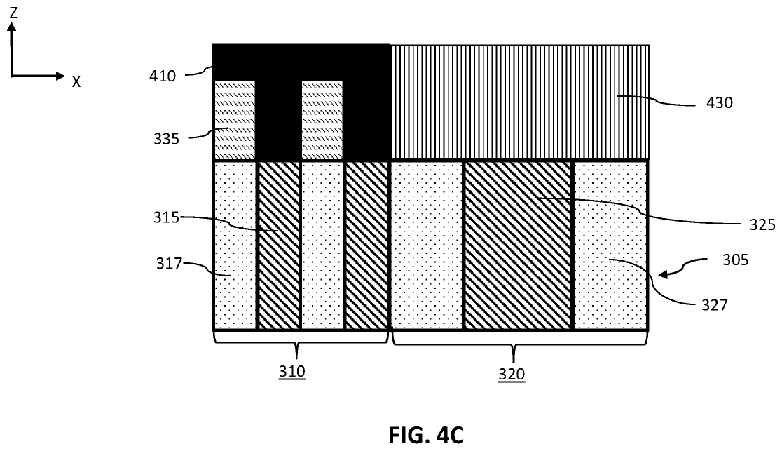

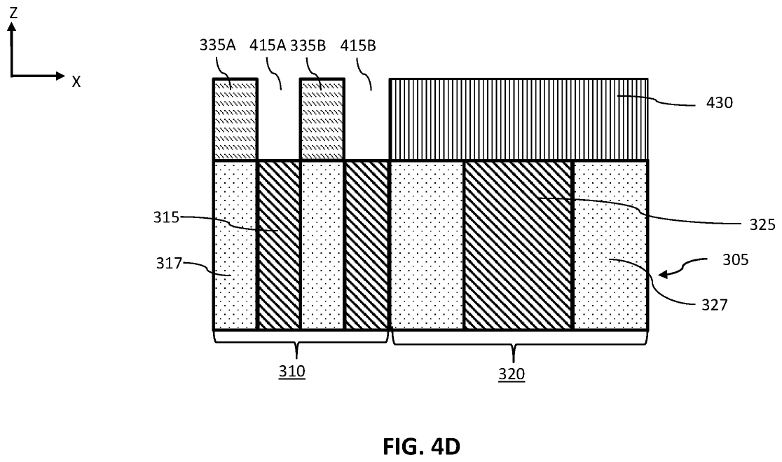

FIGS. 4A-4D illustrate formation of an oxide layer 430 over the loose pitch region 320 of the multi-pitch layer 305, according to some embodiments of the disclosure. The formation process in FIGS. 4A-4D may start after the process in FIG. 3D finishes. In FIG. 4A, a hard mask 410 is formed over the tight pitch region 310. In some embodiments, the hard mask 410 is formed by providing (e.g., depositing) a hard mask material towards the tight pitch region 310. The hard mask material may be deposited by chemical vapor deposition (CVD, such as plasma enhanced CVD), atomic layer deposition (ALD), physical vapor deposition (PVD), other types of deposition techniques, or some combination thereof.

A portion of the hard mask 410 fills the openings 339A and 339B. Another portion of the hard mask 410 is present over the lamellar structures 335. The hard mask material may be ashable, meaning the hard mask material can be removed through ashing. In some embodiments, the hard mask material may include carbon, such as amorphous carbon. Additionally or alternatively, the hard mask material may include other materials, such as hydrogen, one or more dopants (e.g., nitrogen, fluorine, boron, and silicon, etc.), and so on. The bonding structure of the hard mask material can vary from sp² (graphite-like) or sp³ (diamond-like), or a combination of both, depending on the deposition conditions.

In FIG. 4B, a dielectric material 420 is provided over the tight pitch region 310 and the loose pitch region 320. The dielectric material 420 may be deposited towards the tight pitch region 310 and the loose pitch region 320. In some embodiments, the dielectric material 420 may include an oxide, such as silicon oxide. As shown in FIG. 4B, a portion of the dielectric material 420 is over the hard mask 410, and another portion of the dielectric material 420 is over the loose pitch region 320.

In FIG. 4C, the oxide layer 430 is formed over the loose pitch region 320 by removing some of the dielectric material 420, e.g., through etch, polish, or a combination of both. The hard mask 410 may be barely removed or not removed at all. The hard mask material may have a rigidity that is greater than the dielectric material 420. In some embodiments (e.g., embodiments where the dielectric material 420 is removed through etching), the higher rigidity of the hard mask material makes the hard mask 410 insignificantly etched or not etched at all during the etching process. As the hard mask 410 at least partially surrounds the lamellar structures 335, the hard mask 410 can prevent the lamellar structures 335 from being etched for polished in the process of etching or polishing the dielectric material 420, even though the lamellar structures 335 may have a lower rigidity than the dielectric material 420. Without the hard mask 410, the lamellar structures 335 would be exposed and can be etched or polished.

In FIG. 4D, the hard mask 410 is removed, and openings 415A and 415B are formed. In some embodiments, the hard mask 410 is remove through ashing, such as plasma ashing, dry striping, and so on. In some embodiments, the ashing may be performed by an oxygen-rich dry etch. Oxygen may be introduced in a chamber under vacuum. Oxygen radicals in plasma may be created to react with the hard mask material and oxidize the hard mask material to water (H₂O), carbon monoxide (CO), or carbon dioxide (CO₂). Remaining residue of the hard mask material may be removed by wet or dry etching processes after ashing. As shown in FIG. 4D, after the hard mask 410 is removed, the lamellar structures 335 are over the tight pitch region 310, and the oxide layer 430 is over the loose pitch region 320.

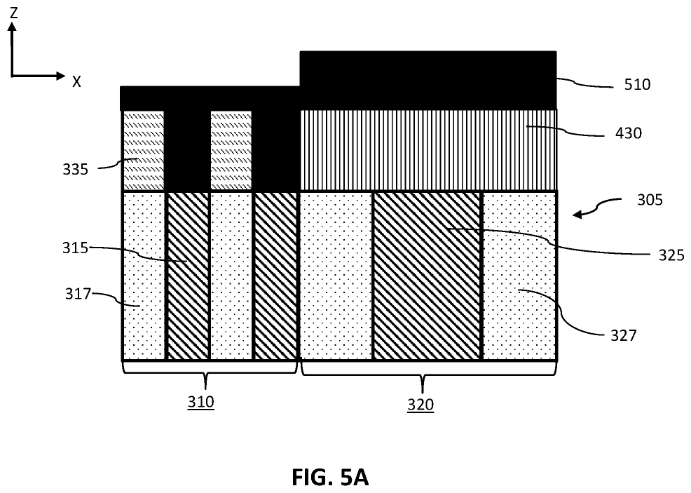

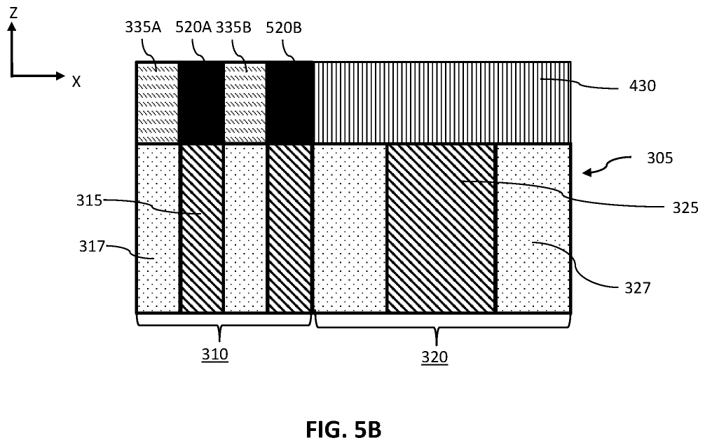

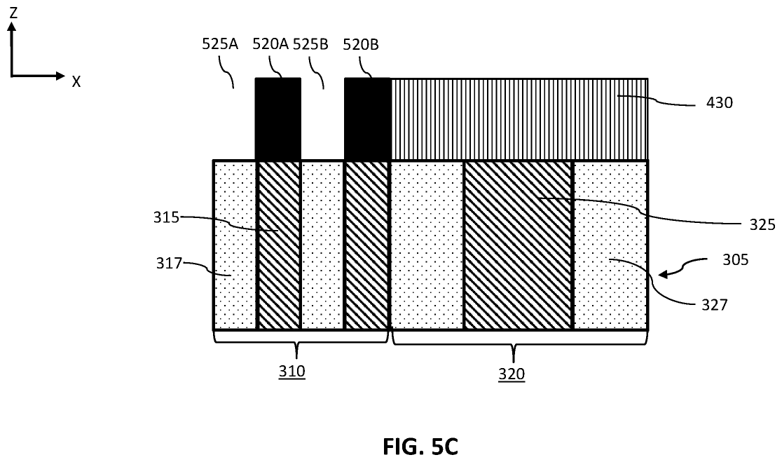

FIGS. 5A-5C illustrate formation of nitride structures 520A and 520B over the tight pitch region 310 of the multi-pitch layer 305, according to some embodiments of the disclosure. In FIG. 5A, a dielectric material 510 is deposited over the tight pitch region 310 and the loose pitch region 320. The dielectric material 510 may be deposited onto the exposed surfaces of the lamellar structures 335, the tight pitch region 310, and the oxide layer 430. The dielectric material 510 may be deposited through CVD, PVD, ALD, and so on. The dielectric material 510 may include a nitride, such as silicon nitride.

In FIG. 5B, a portion of the dielectric material 510 is removed, e.g., through polish. In some embodiments, the dielectric material 510 may be planarized till the top surface of the lamellar structures 335 is reached. The lamellar structures 335 may be barely removed or not removed at all in the process of polishing the dielectric material 510. Nitride structures 520A and 520B (collectively referred to as “nitride structures 520” or “nitride structure 520”) are formed. The nitride structures 520 and lamellar structures 335 may follow the DSA pattern formed in FIG. 3B. In some embodiments, the position or dimension of the nitride structure 520A is the same or similar as the lamellar structure 337A, and the position or dimension of the nitride structure 520B is the same or similar as the lamellar structure 337B. The nitride structures 520 and lamellar structures 335 constitute a repetitive alternating pattern. The dimension of a nitride structure 520 along the Z axis may be the same or similar as the dimension of a lamellar structure 335 along the Z axis. In some embodiments, the top surfaces of nitride structures 520 are aligned with the top surfaces of the lamellar structures 335 in the X-Y. Also, the top surfaces of nitride structures 520 may be aligned with the top surface of the oxide layer 430 in the X-Y plane.

In FIG. 5C, the lamellar structures 335 are removed, e.g., by ashing the polymer in the lamellar structures 335. Openings 525A and 525B are formed. The openings 525A and 525B are located at where the lamellar structures 335 were located.

FIGS. 6A-6D illustrate formation of extra insulators for a tight pitch region 610 of a multi-pitch layer 605, according to some embodiments of the disclosure. The multi-pitch layer 605 may be an embodiment of the multi-pitch layer 305 in FIG. 3. As shown in FIG. 6A, the multi-pitch layer 605 includes a tight pitch region 610 and a loose pitch region 620. The tight pitch region 610 may be an embodiment of the tight pitch region 310 in FIG. 3. The loose pitch region 620 may be an embodiment of the loose pitch region 320 in FIG. 3. In other embodiments, the multi-pitch layer 605 may include more or different regions. For instance, the multi-pitch layer 605 may include another active region arranged at the opposite side of the loose pitch region 620 from the tight pitch region 610.

As shown in FIG. 6A, the tight pitch region 610 include conductive structures 615 (individually referred to as “conductive structure 615”) and insulative structures 617 (individually referred to as “insulative structure 617”). The conductive structures 615 alternative with the insulative structures 617. The conductive structures 615 have longitudinal axes along the Z axis. Two adjacent conductive structures 615 are separated and insulated by an insulative structure 617. The conductive structures 615 may be embodiments of the conductive structures 315 in FIG. 3, the gate contact 135A in FIG. 1, or the metal lines 185 in FIG. 1. An insulative structure 617 includes an insulative structure 616 and an insulative structure 618. The insulative structure 618 may at least partially surround the insulative structure 616. In some embodiments, the insulative structure 616 and the insulative structure 618 include different materials. For instance, the insulative structure 616 includes an oxide, e.g., silicon oxide, and the insulative structure 618 includes a nitride, e.g., silicon nitride.

The loose pitch region 620 include a conductive structure 625 and insulative structures 627 (individually referred to as “insulative structure 627”). The conductive structure 625 is separated from a conductive structure 615 (i.e., the conductive structure 615 that is closest to the conductive structure 625) by an insulative structure 627 (i.e., the insulative structure 627 between the conductive structure 615 and the conductive structure 625). Even though FIG. 6A shows one conductive structure 625 in the transition region, the loose pitch region 620 may include multiple conductive structures 625, which may be separated by insulative structures 627 that alternate with the conductive structures 625. The loose pitch region 620 has a larger pitch than the tight pitch region 610. The conductive structure 625 may be an embodiment of the conductive structure 325 in FIG. 3A, the gate contact 135B in FIG. 1, or the metal line 185 in FIG. 1.

The conductive structure 625 may be embodiments of the conductive structure 325 in FIG. 3. An insulative structure 627 includes an insulative structure 626 and an insulative structure 628. The insulative structure 628 may at least partially surround the insulative structure 626. In some embodiments, the insulative structure 626 and the insulative structure 628 include different materials. For instance, the insulative structure 626 includes an oxide, e.g., silicon oxide, and the insulative structure 628 includes a nitride, e.g., silicon nitride. In some embodiments, the insulative structure 618 or 628 may be referred to as a spacer or liner. The insulative structures 618 and 628 may include a same material, such as silicon nitride.

Nitride structures 620A and 620B are over the conductive structures 615. The nitride structures 620A and 620B are separated by an opening over the insulative structure 617 between the conductive structures 615. Edges of the nitride structure 620A or 620B along the Z axis may be aligned with edges of the corresponding conductive structure 615 along the Z axis. The nitride structures 620A and 620B may be embodiments of the nitride structures 520A and 520B, respectively. An oxide structure 630 is over the loose pitch region 620. In some embodiments, the oxide structure 630 may contact the nitride structure 620B. The oxide structure 630 may be an embodiment of the oxide layer 430.

In FIG. 6B, the material in the insulative structure 618 is deposited onto the nitride structures 620A and 620B and the oxide structure 630. Insulative structures 640 and 645 are formed. The insulative structure 640 at least partially surrounds the nitride structure 620A and the conductive structure 615 below the nitride structure 620A. A first portion of the insulative structure 645 may be an insulative structure 618. A second portion of the insulative structure 645 may be formed by depositing the material in the insulative structure 618 onto the nitride structure 620A. The second portion of the insulative structure 645 partially wraps around the nitride structure 620A. A part of the second portion of the insulative structure 645 is over the nitride structure 620A.

The insulative structure 645 at least partially surrounds the nitride structure 620B and the conductive structure 615 below the nitride structure 620B. A portion of the insulative structure 645 is over the oxide structure 630. In some embodiments, after the material in the insulative structure 618 is deposited, a portion of the material may be removed (e.g., through etch or polish) to form the insulative structure 640 or 645.

In FIG. 6C, each insulative structure 616 is converted to an insulative structure 650. The insulative structure 650 may include the same material as the insulative structure 616. In some embodiments, the insulative structure 650 is formed by depositing the material in the insulative structure 616 onto the insulative structure 616. The top surface of the insulative structure 650 may be aligned with the top surface of the insulative structures 640 or 650 along the X axis.

In FIG. 6D, the portion of the insulative structure 645, which is over the oxide structure 630, is removed, e.g., through etch or polish. An insulative structure 647, which is the rest of the insulative structure 645 that is not removed, is formed. A portion of the insulative structure 647 is over the nitride structure 620B.

FIGS. 7A-7D illustrate multi-pitch patterning based on the oxide structure 630, according to some embodiments of the disclosure. The one-step flow in FIGS. 7A-7D may be performed after the process in FIG. 6D. In FIG. 7A, a plug 710 is placed over the tight pitch region 610. Particularly, the plug 710 is directly over a portion of the insulative structure 640, a portion of the insulative structure 647, and an insulative structure 650 between the insulative structure 640 and the insulative structure 647. The plug 710 is partially over the nitride structure 620A and partially over the nitride structure 620B. The plug 720 is placed over a portion of the oxide structure 630. In some embodiments, an edge of the plug 720 along the Z axis may be aligned with an edge of an insulative structure 628. In an example, the plug 720 may be over the conductive structure 625 and the two insulative structures 628 contacting the conductive structure 625. Each of the two insulative structures 628 may include an inner edge (i.e., the edge that contacts the conductive structure 625) and an outer edge opposite the inner edge. The edges of the plug 720 along the Z axis may be aligned with the outer edges of the insulative structures 628.

FIG. 7B shows a top view (i.e., a view in the X-Y plane) of the structures in FIG. 7A. FIG. 7A may be a cross-sectional view of the A-B plane shown in FIG. 7B. As shown in FIG. 7B, the plug 710 is not over the whole tight pitch region 610 along the Y axis. The plug 710 can facilitate formation of a trench over the tight pitch region 610. For instance, the trench may be formed in an area over the tight pitch region 610 that is not covered by the plug 710. Similarly, the plug 720 is not over the whole loose pitch region 620 along the Y axis. The plug 720 can facilitate formation of a trench over the loose pitch region 620. For instance, the trench may be formed in an area over the loose pitch region 620 that is not covered by the plug 720.

In FIG. 7C, a trench 715 is formed over the tight pitch region 610, and a trench 725 is formed over the loose pitch region 620. FIG. 7C may be a cross-sectional view in the C-D plane shown in FIG. 7B. The plugs 710 and 720 are shown with dotted lines in FIG. 7C since the plugs 710 and 720 are invisible in the cross-sectional view. The trench 715 may be formed by etching one or more materials in the nitride structures 620A and 620B and the insulative structures 640, 647, and 650. In some embodiments, the nitride structures 620A and 620B and the insulative structures 640 and 647 include a same material, e.g., a nitride. The insulative structure 650 may include a different material, such as an oxide. The area under the plug 710 is not etched. The trench 725 may be formed by etching the oxide in the oxide structure 630. The area under the plug 720 is not etched.

In FIG. 7D, the trench 715 is filled with a dielectric material to form a structure 730. The trench 725 is filled with a dielectric material to form a structure 740. In some embodiments, the dielectric materials in the structures 730 and 740 may be the same. In an example, the structures 730 and 740 both include a nitride, such as silicon nitride. An assembly 700 is formed.

In some embodiments, further fabrication may be performed on the assembly 700 after the process in FIG. 7D, e.g., to form vias or metal lines over the multi-pitch layer 605. For instance, a planarizing or polishing process may be performed to flatten or smooth the top surface of the assembly 700. Additionally or alternatively, openings may be formed in the structures 730 and 740 to form vias (such as the vias 150 in FIG. 1) that are connected to the conductive structures 615 and 625. A metal layer or ILD may be formed over the top surface of the assembly 700.

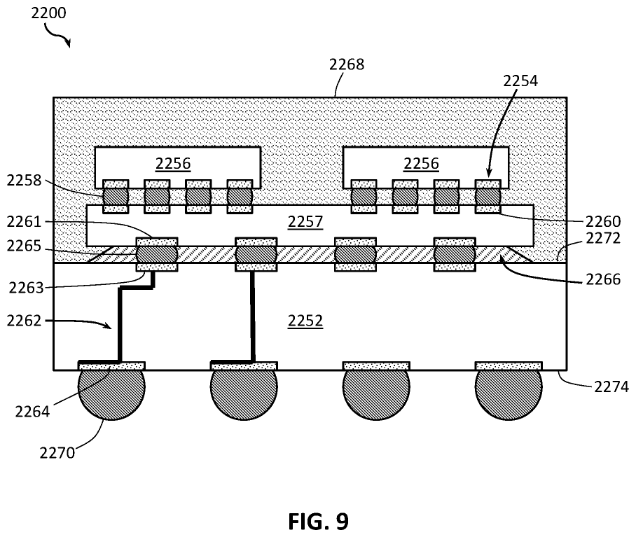

FIGS. 8A-8B are top views of a wafer 2000 and dies 2002 that may include one or more multi-pitch patterns, according to some embodiments of the disclosure. In some embodiments, the dies 2002 may be included in an IC package, according to some embodiments of the disclosure. For example, any of the dies 2002 may serve as any of the dies 2256 in an IC package 2200 shown in FIG. 9. The wafer 2000 may be composed of semiconductor material and may include one or more dies 2002 having IC devices formed on a surface of the wafer 2000. Each of the dies 2002 may be a repeating unit of a semiconductor product that includes any suitable IC (e.g., ICs including one or more multi-pitch patterns as described herein). After the fabrication of the semiconductor product is complete (e.g., after manufacture of metal lines as described herein), the wafer 2000 may undergo a singulation process in which each of the dies 2002 is separated from one another to provide discrete “chips” of the semiconductor product. In particular, devices that include one or more multi-pitch patterns as disclosed herein may take the form of the wafer 2000 (e.g., not singulated) or the form of the die 2002 (e.g., singulated). The die 2002 may include one or more diodes, one or more transistors (e.g., one or more Ill-N transistors as described herein) as well as, optionally, supporting circuitry to route electrical signals to the III-N diodes with n-doped wells and capping layers and III-N transistors, as well as any other IC components. In some embodiments, the wafer 2000 or the die 2002 may implement an electrostatic discharge (ESD) protection device, a radio frequency front-end device, a memory device (e.g., a SRAM device), a logic device (e.g., an AND, OR, NAND, or NOR gate), or any other suitable circuit element. Multiple ones of these devices may be combined on a single die 2002.

FIG. 9 is a side, cross-sectional view of an example IC package 2200 that may include one or more IC devices having one or more multi-pitch patterns, according to some embodiments of the disclosure. In some embodiments, the IC package 2200 may be a system-in-package (SiP).

As shown in FIG. 9, the IC package 2200 may include a package substrate 2252. The package substrate 2252 may be formed of a dielectric material (e.g., a ceramic, a glass, a combination of organic and inorganic materials, a buildup film, an epoxy film having filler particles therein, etc., and may have embedded portions having different materials), and may have conductive pathways extending through the dielectric material between the face 2272 and the face 2274, or between different locations on the face 2272, and/or between different locations on the face 2274.

The package substrate 2252 may include conductive contacts 2263 that are coupled to conductive pathways 2262 through the package substrate 2252, allowing circuitry within the dies 2256 and/or the interposer 2257 to electrically couple to various ones of the conductive contacts 2264 (or to other devices included in the package substrate 2252, not shown).

The IC package 2200 may include an interposer 2257 coupled to the package substrate 2252 via conductive contacts 2261 of the interposer 2257, first-level interconnects 2265, and the conductive contacts 2263 of the package substrate 2252. The first-level interconnects 2265 illustrated in FIG. 9 are solder bumps, but any suitable first-level interconnects 2265 may be used. In some embodiments, no interposer 2257 may be included in the IC package 2200; instead, the dies 2256 may be coupled directly to the conductive contacts 2263 at the face 2272 by first-level interconnects 2265.

The IC package 2200 may include one or more dies 2256 coupled to the interposer 2257 via conductive contacts 2254 of the dies 2256, first-level interconnects 2258, and conductive contacts 2260 of the interposer 2257. The conductive contacts 2260 may be coupled to conductive pathways (not shown) through the interposer 2257, allowing circuitry within the dies 2256 to electrically couple to various ones of the conductive contacts 2261 (or to other devices included in the interposer 2257, not shown). The first-level interconnects 2258 illustrated in FIG. 9 are solder bumps, but any suitable first-level interconnects 2258 may be used. As used herein, a “conductive contact” may refer to a portion of electrically conductive material (e.g., metal) serving as an interface between different components; conductive contacts may be recessed in, flush with, or extending away from a surface of a component, and may take any suitable form (e.g., a conductive pad or socket).

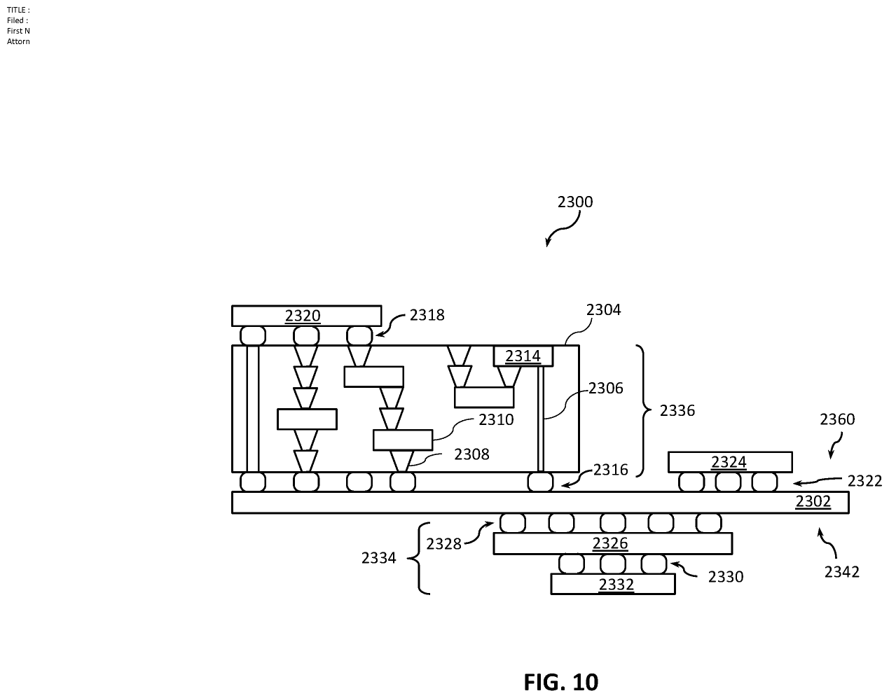

In some embodiments, an underfill material 2266 may be disposed between the package substrate 2252 and the interposer 2257 around the first-level interconnects 2265, and a mold compound 2268 may be disposed around the dies 2256 and the interposer 2257 and in contact with the package substrate 2252. In some embodiments, the underfill material 2266 may be the same as the mold compound 2268. Example materials that may be used for the underfill material 2266 and the mold compound 2268 are epoxy mold materials, as suitable. Second-level interconnects 2270 may be coupled to the conductive contacts 2264. The second-level interconnects 2270 illustrated in FIG. 9 are solder balls (e.g., for a ball grid array arrangement), but any suitable second-level interconnects 22770 may be used (e.g., pins in a pin grid array arrangement or lands in a land grid array arrangement). The second-level interconnects 2270 may be used to couple the IC package 2200 to another component, such as a circuit board (e.g., a motherboard), an interposer, or another IC package, as known in the art and as discussed below with reference to FIG. 10.

The dies 2256 may take the form of any of the embodiments of the die 2002 discussed herein and may include any of the embodiments of an IC device having one or more multi-pitch patterns. In embodiments in which the IC package 2200 includes multiple dies 2256, the IC package 2200 may be referred to as a multi-chip package. Importantly, even in such embodiments of an MCP implementation of the IC package 2200, one or more multi-pitch patterns may be provided in a single chip, in accordance with any of the embodiments described herein. The dies 2256 may include circuitry to perform any desired functionality. For example, one or more of the dies 2256 may be ESD protection dies, including one or more multi-pitch patterns as described herein, one or more of the dies 2256 may be logic dies (e.g., silicon-based dies), one or more of the dies 2256 may be memory dies (e.g., high bandwidth memory), etc. In some embodiments, any of the dies 2256 may include one or more multi-pitch patterns, e.g., metal lines as discussed above; in some embodiments, at least some of the dies 2256 may not include any Ill-N diodes with n-doped wells and capping layers.

The IC package 2200 illustrated in FIG. 9 may be a flip chip package, although other package architectures may be used. For example, the IC package 2200 may be a ball grid array (BGA) package, such as an embedded wafer-level ball grid array (eWLB) package. In another example, the IC package 2200 may be a wafer-level chip scale package (WLCSP) or a panel fan-out (FO) package. Although two dies 2256 are illustrated in the IC package 2200 of FIG. 9, an IC package 2200 may include any desired number of the dies 2256. An IC package 2200 may include additional passive components, such as surface-mount resistors, capacitors, and inductors disposed on the first face 2272 or the second face 2274 of the package substrate 2252, or on either face of the interposer 2257. More generally, an IC package 2200 may include any other active or passive components known in the art.

FIG. 10 is a cross-sectional side view of an IC device assembly 2300 that may include components having one or more IC devices implementing one or more multi-pitch patterns, according to some embodiments of the disclosure. The IC device assembly 2300 includes a number of components disposed on a circuit board 2302 (which may be, e.g., a motherboard). The IC device assembly 2300 includes components disposed on a first face 2340 of the circuit board 2302 and an opposing second face 2342 of the circuit board 2302; generally, components may be disposed on one or both faces 2340 and 2342. In particular, any suitable ones of the components of the IC device assembly 2300 may include any of the IC devices implementing one or more multi-pitch patterns in accordance with any of the embodiments disclosed herein; e.g., any of the IC packages discussed below with reference to the IC device assembly 2300 may take the form of any of the embodiments of the IC package 2200 discussed above with reference to FIG. 9 (e.g., may include one or more multi-pitch patterns in/on a die 2256).

In some embodiments, the circuit board 2302 may be a PCB including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 2302. In other embodiments, the circuit board 2302 may be a non-PCB substrate.

The IC device assembly 2300 illustrated in FIG. 10 includes a package-on-interposer structure 2336 coupled to the first face 2340 of the circuit board 2302 by coupling components 2316. The coupling components 2316 may electrically and mechanically couple the package-on-interposer structure 2336 to the circuit board 2302, and may include solder balls (e.g., as shown in FIG. 10), male and female portions of a socket, an adhesive, an underfill material, and/or any other suitable electrical and/or mechanical coupling structure.

The package-on-interposer structure 2336 may include an IC package 2320 coupled to an interposer 2304 by coupling components 2318. The coupling components 2318 may take any suitable form for the application, such as the forms discussed above with reference to the coupling components 2316. The IC package 2320 may be or include, for example, a die (the die 2002 of FIG. 8B), an IC device (e.g., the IC device of FIG. 1), or any other suitable component. In particular, the IC package 2320 may include one or more multi-pitch patterns as described herein. Although a single IC package 2320 is shown in FIG. 10, multiple IC packages may be coupled to the interposer 2304; indeed, additional interposers may be coupled to the interposer 2304. The interposer 2304 may provide an intervening substrate used to bridge the circuit board 2302 and the IC package 2320. Generally, the interposer 2304 may spread a connection to a loose pitch or reroute a connection to a different connection. For example, the interposer 2304 may couple the IC package 2320 (e.g., a die) to a BGA of the coupling components 2316 for coupling to the circuit board 2302. In the embodiment illustrated in FIG. 10, the IC package 2320 and the circuit board 2302 are attached to opposing sides of the interposer 2304; in other embodiments, the IC package 2320 and the circuit board 2302 may be attached to a same side of the interposer 2304. In some embodiments, three or more components may be interconnected by way of the interposer 2304.

The interposer 2304 may be formed of an epoxy resin, a fiberglass-reinforced epoxy resin, a ceramic material, or a polymer material such as polyimide. In some implementations, the interposer 2304 may be formed of alternate rigid or flexible materials that may include the same materials described above for use in a semiconductor substrate, such as silicon, germanium, and other group III-V and group IV materials. The interposer 2304 may include metal interconnects 2308 and vias 2310, including but not limited to TSVs 2306. The interposer 2304 may further include embedded devices 2314, including both passive and active devices. Such devices may include, but are not limited to, capacitors, decoupling capacitors, resistors, inductors, fuses, diodes, transformers, sensors, ESD protection devices, and memory devices. More complex devices such as further RF devices, power amplifiers, power management devices, antennas, arrays, sensors, and microelectromechanical systems (MEMS) devices may also be formed on the interposer 2304. In some embodiments, the IC devices implementing one or more multi-pitch patterns as described herein may also be implemented in/on the interposer 2304. The package-on-interposer structure 2336 may take the form of any of the package-on-interposer structures known in the art.

The IC device assembly 2300 may include an IC package 2324 coupled to the first face 2340 of the circuit board 2302 by coupling components 2322. The coupling components 2322 may take the form of any of the embodiments discussed above with reference to the coupling components 2316, and the IC package 2324 may take the form of any of the embodiments discussed above with reference to the IC package 2320.

The IC device assembly 2300 illustrated in FIG. 10 includes a package-on-package structure 2334 coupled to the second face 2342 of the circuit board 2302 by coupling components 2328. The package-on-package structure 2334 may include an IC package 2326 and an IC package 2332 coupled together by coupling components 2

such that the IC package 2326 is disposed between the circuit board 2302 and the IC package 2332. The coupling components 2328 and 2330 may take the form of any of the embodiments of the coupling components 2316 discussed above, and the IC packages 2326 and 2332 may take the form of any of the embodiments of the IC package 2320 discussed above. The package-on-package structure 2334 may be configured in accordance with any of the package-on-package structures known in the art.

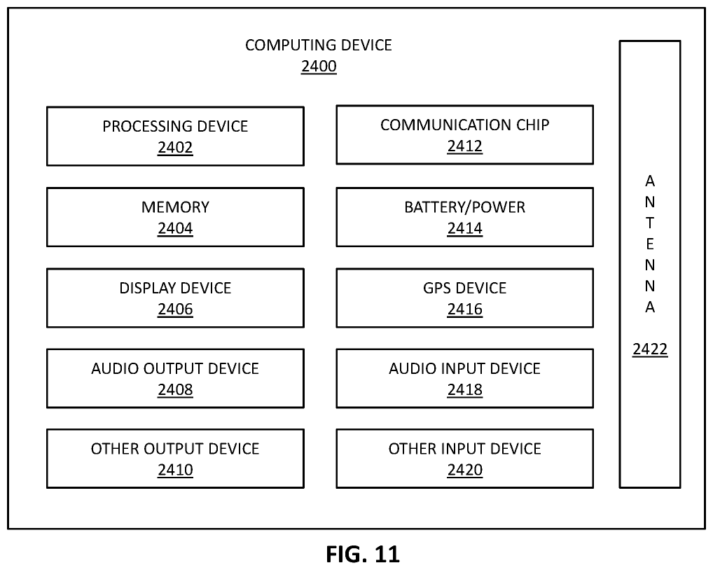

FIG. 11 is a block diagram of an example computing device 2400 that may include one or more components with one or more IC devices having one or more multi-pitch patterns, according to some embodiments of the disclosure. For example, any suitable ones of the components of the computing device 2400 may include a die (e.g., the die 2002 of FIG. 8B) including one or more multi-pitch patterns, according to some embodiments of the disclosure. Any of the components of the computing device 2400 may include an IC device (e.g., the IC devices in FIGS. 1A and 1B) and/or an IC package (e.g., the IC package 2200 of FIG. 9). Any of the components of the computing device 2400 may include an IC device assembly (e.g., the IC device assembly 2300 of FIG. 10).

A number of components are illustrated in FIG. 11 as included in the computing device 2400, but any one or more of these components may be omitted or duplicated, as suitable for the application. In some embodiments, some or all of the components included in the computing device 2400 may be attached to one or more motherboards. In some embodiments, some or all of these components are fabricated onto a single SoC (system-on-chip) die.

Additionally, in various embodiments, the computing device 2400 may not include one or more of the components illustrated in FIG. 11, but the computing device 2400 may include interface circuitry for coupling to the one or more components. For example, the computing device 2400 may not include a display device 2406, but may include display device interface circuitry (e.g., a connector and driver circuitry) to which a display device 2406 may be coupled. In another set of examples, the computing device 2400 may not include an audio input device 2418 or an audio output device 2408, but may include audio input or output device interface circuitry (e.g., connectors and supporting circuitry) to which an audio input device 2418 or audio output device 2408 may be coupled.

The computing device 2400 may include a processing device 2402 (e.g., one or more processing devices). As used herein, the term “processing device” or “processor” may refer to any device or portion of a device that processes electronic data from registers and/or memory to transform that electronic data into other electronic data that may be stored in registers and/or memory. The processing device 2402 may include one or more digital signal processors (DSPs), application-specific ICs (ASICs), central processing units (CPUs), graphics processing units (GPUs), cryptoprocessors (specialized processors that execute cryptographic algorithms within hardware), server processors, or any other suitable processing devices. The computing device 2400 may include a memory 2404, which may itself include one or more memory devices such as volatile memory (e.g., DRAM), nonvolatile memory (e.g., read-only memory (ROM)), flash memory, solid-state memory, and/or a hard drive. In some embodiments, the memory 2404 may include memory that shares a die with the processing device 2402. This memory may be used as cache memory and may include, e.g., eDRAM, and/or spin transfer torque magnetic random-access memory (STT-MRAM).

In some embodiments, the computing device 2400 may include a communication chip 2412 (e.g., one or more communication chips). For example, the communication chip 2412 may be configured for managing wireless communications for the transfer of data to and from the computing device 2400. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

The communication chip 2412 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultramobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 2412 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 2412 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 2412 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 2412 may operate in accordance with other wireless protocols in other embodiments. The computing device 2400 may include an antenna 2422 to facilitate wireless communications and/or to receive other wireless communications (such as AM or FM radio transmissions).

In some embodiments, the communication chip 2412 may manage wired communications, such as electrical, optical, or any other suitable communication protocols (e.g., the Ethernet). As noted above, the communication chip 2412 may include multiple communication chips. For instance, a first communication chip 2412 may be dedicated to shorter-range wireless communications such as Wi-Fi or Bluetooth, and a second communication chip 2412 may be dedicated to longer-range wireless communications such as global positioning system (GPS), EDGE, GPRS, CDMA, WiMAX, LTE, EV-DO, or others. In some embodiments, a first communication chip 2412 may be dedicated to wireless communications, and a second communication chip 2412 may be dedicated to wired communications.

In various embodiments, IC devices as described herein may be particularly advantageous for use as part of ESD circuits protecting power amplifiers, low-noise amplifiers, filters (including arrays of filters and filter banks), switches, or other active components. In some embodiments, IC devices as described herein may be used in PMICs, e.g., as a rectifying diode for large currents. In some embodiments, IC devices as described herein may be used in audio devices and/or in various input/output devices.

The computing device 2400 may include battery/power circuitry 2414. The battery/power circuitry 2414 may include one or more energy storage devices (e.g., batteries or capacitors) and/or circuitry for coupling components of the computing device 2400 to an energy source separate from the computing device 2400 (e.g., AC line power).

The computing device 2400 may include a display device 2406 (or corresponding interface circuitry, as discussed above). The display device 2406 may include any visual indicators, such as a heads-up display, a computer monitor, a projector, a touchscreen display, a liquid crystal display (LCD), a light-emitting diode display, or a flat panel display, for example.

The computing device 2400 may include an audio output device 2408 (or corresponding interface circuitry, as discussed above). The audio output device 2408 may include any device that generates an audible indicator, such as speakers, headsets, or earbuds, for example.

The computing device 2400 may include an audio input device 2418 (or corresponding interface circuitry, as discussed above). The audio input device 2418 may include any device that generates a signal representative of a sound, such as microphones, microphone arrays, or digital instruments (e.g., instruments having a musical instrument digital interface (MIDI) output).

The computing device 2400 may include a GPS device 2416 (or corresponding interface circuitry, as discussed above). The GPS device 2416 may be in communication with a satellite-based system and may receive a location of the computing device 2400, as known in the art.

The computing device 2400 may include an other output device 2410 (or corresponding interface circuitry, as discussed above). Examples of the other output device 2410 may include an audio codec, a video codec, a printer, a wired or wireless transmitter for providing information to other devices, or an additional storage device.

The computing device 2400 may include an other input device 2420 (or corresponding interface circuitry, as discussed above). Examples of the other input device 2420 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The computing device 2400 may have any desired form factor, such as a handheld or mobile computing device (e.g., a cell phone, a smart phone, a mobile internet device, a music player, a tablet computer, a laptop computer, a netbook computer, an ultrabook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device. In some embodiments, the computing device 2400 may be any other electronic device that processes data.

The following paragraphs provide various examples of the embodiments disclosed herein.

Example 1 provides an IC device, including a first layer, including a first conductive structure, and a second conductive structure, where the second conductive structure is in parallel with the first conductive structure in a first direction, and a dimension of the second conductive structure in a second direction perpendicular to the first direction is greater than a dimension of the first conductive structure in the second direction; a second layer over the first layer, the second layer including a first structure over the first conductive structure, the first structure including a first dielectric material, a second structure over the second conductive structure, the second structure including the first dielectric material, and a third structure at least partially surrounding the second structure, the third structure including a second dielectric material that is different from the first dielectric material.

Example 2 provides the IC device according to example 1, where the second dielectric material includes silicon oxide.

Example 3 provides the IC device according to example 1 or 2, where the first dielectric material includes silicon nitride.

Example 4 provides the IC device according to any of the preceding examples, where the second structure is a guard ring of the second transistor.

Example 5 provides the IC device according to any of the preceding examples, where the first layer further includes an insulative structure between the first gate contact and the second gate contact, and a portion of the third structure is over the insulative structure.

Example 6 provides the IC device according to example 5, where the insulative structure includes a first electrical insulator and a second electrical insulator, the first electrical insulator surrounds the second electrical insulator at least partially, and a portion of the second structure is over a portion of the first electrical insulator.

Example 7 provides the IC device according to example 6, where the first electrical insulator includes the first dielectric material, or the second electrical insulator includes the second dielectric material.

Example 8 provides an IC device, including a transistor, including a channel region, and a gate contact over at least part of the channel region; a via over the gate contact, the via connected to the gate contact; a first structure over the gate contact, the first structure at least partially surrounding the via and including a first dielectric material that includes a nitride; and a second structure at least partially surrounding the first structure, the second structure including a second dielectric material that includes an oxide.

Example 9 provides the IC device according to example 8, further including an additional transistor including an additional channel region and an additional gate contact over at least part of the additional channel region, where the additional gate contact is in parallel with the gate contact in a first direction, a dimension of the gate contact in a second direction is greater than a dimension of the additional gate contact in the second direction, and the second direction is perpendicular to the first direction.

Example 10 provides the IC device according to example 9, further including a third structure over the additional gate contact, the third structure including the first dielectric material.

Example 11 provides the IC device according to example 10, further including an additional via connected to the additional gate contact, where the additional via is at least partially surrounded by the third structure.

Example 12 provides the IC device according to any one of examples 8-11, where the nitride includes silicon nitride, and the oxide includes silicon oxide.

Example 13 provides a method for forming an IC device, including forming a lamellar pattern over a first section of a layer through DSA of a block copolymer, the first section including a first conductive structure; forming a first structure over the first conductive structure based on the lamellar pattern, the first structure including a first dielectric material; forming a second structure over a second section of the layer, the second structure including a second dielectric material that is different from the first dielectric material, the second section including a second conductive structure; forming an insulative structure based on the lamellar pattern, the insulative structure at least partially surrounding the first structure; providing a first plug and a second plug, where at least a portion of the first plug is over at least a portion of the insulative structure, and the second plug is over the second structure; and forming a first opening in the first structure based on the first plug and forming a second opening in the second structure based on the second plug; and filling at least part of the first opening or the second opening with the first dielectric material.

Example 14 provides the method according to example 13, where the second conductive structure is in parallel with the first conductive structure in a first direction, a dimension of the second conductive structure in a second direction is greater than a dimension of the first conductive structure in the second direction, and the second direction is perpendicular to the first direction.

Example 15 provides the method according to example 14, where a dimension of the second opening in the second direction is greater than the dimension of the second conductive structure.

Example 16 provides the method according to any one of examples 13-15, where forming the lamellar pattern over the first section of the layer through the DSA of the block copolymer includes forming lamellar structures over the layer through the DSA of the block copolymer, where one or more lamellar structures are over the second section of the layer; and removing the one or more lamellar structures.

Example 17 provides the method according to any one of examples 13-16, where the lamellar pattern includes a lamellar structure, and the lamellar structure includes a polymer in the block copolymer.

Example 18 provides the method according to example 17, where forming the insulative structure based on the lamellar pattern includes forming an opening by removing the lamellar structure; providing a first electrical insulator into a first portion of the opening, the first electrical insulator at least partially surrounding the first structure; and providing a second electrical insulator into a second portion of the opening, where the insulative structure includes the first electrical insulator and the second electrical insulator.

Example 19 provides the method according to any one of examples 13-18, where forming the first opening in the first structure based on the first plug includes forming the first opening in a portion of the first structure, where the portion of the first structure is not over the first plug.

Example 20 provides the method according to any one of examples 13-19, where forming the second opening in the second structure based on the second plug includes forming the second opening in a portion of the second structure, where the portion of the second structure is not over the second plug.

Example 21 provides an IC package, including the IC device according to any one of examples 1-12; and a further IC component, coupled to the device.

Example 22 provides the IC package according to example 21, where the further IC component includes one of a package substrate, an interposer, or a further IC die.

Example 23 provides the IC package according to example 21 or 22, where the IC device according to any one of examples 1-12 may include, or be a part of, at least one of a memory device, a computing device, a wearable device, a handheld electronic device, and a wireless communications device.

Example 24 provides an electronic device, including a carrier substrate; and one or more of the IC devices according to any one of examples 1-12 and the IC package according to any one of examples 21-23, coupled to the carrier substrate.

Example 25 provides the electronic device according to example 24, where the carrier substrate is a motherboard.

Example 26 provides the electronic device according to example 24, where the carrier substrate is a PCB.

Example 27 provides the electronic device according to any one of examples 24-26, where the electronic device is a wearable electronic device or handheld electronic device.

Example 28 provides the electronic device according to any one of examples 24-27, where the electronic device further includes one or more communication chips and an antenna.

Example 29 provides the electronic device according to any one of examples 24-28, where the electronic device is an RF transceiver.

Example 30 provides the electronic device according to any one of examples 24-28, where the electronic device is one of a switch, a power amplifier, a low-noise amplifier, a filter, a filter bank, a duplexer, an upconverter, or a downconverter of an RF communications device, e.g., of an RF transceiver.

Example 31 provides the electronic device according to any one of examples 24-30, where the electronic device is a computing device.

Example 32 provides the electronic device according to any one of examples 24-31, where the electronic device is included in a base station of a wireless communication system.

Example 33 provides the electronic device according to any one of examples 24-31, where the electronic device is included in a user equipment device of a wireless communication system.

Example 34 provides the method according to any one of examples 13-20, further including processes for forming the IC device according to any one of claims 1-12.

Example 35 provides the method according to any one of examples 13-20, further including processes for forming the IC package according to any one of the claims 21-23.

Example 36 provides the method according to any one of examples 13-20, further including processes for forming the electronic device according to any one of the claims 24-33.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize. These modifications may be made to the disclosure in light of the above detailed description.

1. An integrated circuit (IC) device, comprising:
a first layer, comprising:
a first conductive structure, and
a second conductive structure,
wherein the second conductive structure is in parallel with the first conductive structure in a first direction, and a dimension of the second conductive structure in a second direction perpendicular to the first direction is greater than a dimension of the first conductive structure in the second direction;
a second layer over the first layer, the second layer comprising:
a first structure over the first conductive structure, the first structure comprising a first dielectric material,
a second structure over the second conductive structure, the second structure comprising the first dielectric material, and
a third structure at least partially surrounding the second structure, the third structure comprising a second dielectric material that is different from the first dielectric material.

2. The IC device according to claim 1, wherein the second dielectric material comprises silicon oxide.

3. The IC device according to claim 1, wherein the first dielectric material comprises silicon nitride.

4. The IC device according to claim 1, wherein the second structure is a guard ring of the second transistor.

5. The IC device according to claim 1, wherein:
the first layer further comprises an insulative structure between the first gate contact and the second gate contact, and
a portion of the third structure is over the insulative structure.

6. The IC device according to claim 5, wherein:
the insulative structure comprises a first electrical insulator and a second electrical insulator,
the first electrical insulator surrounds the second electrical insulator at least partially, and
a portion of the second structure is over a portion of the first electrical insulator.

7. The IC device according to claim 6, wherein:
the first electrical insulator comprises the first dielectric material, or
the second electrical insulator comprises the second dielectric material.

8. An integrated circuit (IC) device, comprising:
a transistor, comprising:
a channel region, and
a gate contact over at least part of the channel region;
a via over the gate contact, the via connected to the gate contact;
a first structure over the gate contact, the first structure at least partially surrounding the via and comprising a first dielectric material that includes a nitride; and
a second structure at least partially surrounding the first structure, the second structure comprising a second dielectric material that includes an oxide.

9. The IC device according to claim 8, further comprising:
an additional transistor comprising an additional channel region and an additional gate contact over at least part of the additional channel region,
wherein the additional gate contact is in parallel with the gate contact in a first direction, a dimension of the gate contact in a second direction is greater than a dimension of the additional gate contact in the second direction, and the second direction is perpendicular to the first direction.

10. The IC device according to claim 9, further comprising:
a third structure over the additional gate contact, the third structure comprising the first dielectric material.

11. The IC device according to claim 10, further comprising:
an additional via connected to the additional gate contact,
wherein the additional via is at least partially surrounded by the third structure.

12. The IC device according to claim 8, wherein the nitride comprises silicon nitride, and the oxide comprises silicon oxide.

13. A method for forming an integrated circuit (IC) device, comprising:
forming a lamellar pattern over a first section of a layer through directed self-assembly of a block copolymer, the first section comprising a first conductive structure;
forming a first structure over the first conductive structure based on the lamellar pattern, the first structure comprising a first dielectric material;
forming a second structure over a second section of the layer, the second structure comprising a second dielectric material that is different from the first dielectric material, the second section comprising a second conductive structure;
forming an insulative structure based on the lamellar pattern, the insulative structure at least partially surrounding the first structure;
providing a first plug and a second plug, wherein at least a portion of the first plug is over at least a portion of the insulative structure, and the second plug is over the second structure;
forming a first opening in the first structure based on the first plug and forming a second opening in the second structure based on the second plug; and
filling at least part of the first opening or the second opening with the first dielectric material.

14. The method according to claim 13, wherein:
the second conductive structure is in parallel with the first conductive structure in a first direction,
a dimension of the second conductive structure in a second direction is greater than a dimension of the first conductive structure in the second direction, and
the second direction is perpendicular to the first direction.

15. The method according to claim 14, wherein a dimension of the second opening in the second direction is greater than the dimension of the second conductive structure.

16. The method according to claim 13, wherein forming the lamellar pattern over the first section of the layer through the directed self-assembly of the block copolymer comprises:
forming lamellar structures over the layer through the directed self-assembly of the block copolymer, wherein one or more lamellar structures are over the second section of the layer; and
removing the one or more lamellar structures.

17. The method according to claim 13, wherein the lamellar pattern comprises a lamellar structure, and the lamellar structure comprises a polymer in the block copolymer.

18. The method according to claim 17, wherein forming the insulative structure based on the lamellar pattern comprises:
forming an opening by removing the lamellar structure;
providing a first electrical insulator into a first portion of the opening, the first electrical insulator at least partially surrounding the first structure; and
providing a second electrical insulator into a second portion of the opening,
wherein the insulative structure comprises the first electrical insulator and the second electrical insulator.

19. The method according to claim 13, wherein forming the first opening in the first structure based on the first plug comprises:
forming the first opening in a portion of the first structure, wherein the portion of the first structure is not over the first plug.

20. The method according to claim 13, wherein forming the second opening in the second structure based on the second plug comprises:
forming the second opening in a portion of the second structure, wherein the portion of the second structure is not over the second plug.
